(19) United States
(12) Patent Application Publication
(10) Pub. No.: US 2026/0068119 A1
(43) Pub. Date: Mar. 5, 2026

(54) SEMICONDUCTOR DEVICE AND METHOD FOR FABRICATING THE SAME

(71) Applicant: SK hynix Inc., Gyeonggi-do (KR)

(72) Inventor: Dong Il SONG, Gyeonggi-do (KR)

(21) Appl. No.: 19/004,474

(22) Filed: Dec. 30, 2024

(30) Foreign Application Priority Data
Sep. 2, 2024 (KR) 10-2024-0118377

(51) Int. Cl. H10B 12/00

(52) U.S. Cl. CPC H10B 12/30; H10B 12/03; H10B 12/05

(57) ABSTRACT

The embodiments of the present disclosure are directed to a semiconductor device including high-integrated memory cells and a method for fabricating the semiconductor device, and the semiconductor device may include a plurality of nano sheets that are vertically stacked; a first conductive line coupled in common to first edges of the nano sheets, the first conductive line being oriented vertically; a plurality of data storage elements, each data storage element being coupled to second edges of the nano sheets; a plurality of second conductive lines, each second conductive line surrounding the nano sheets and being oriented horizontally; and a plurality of inter-cell dielectric layers disposed between the second conductive lines and each including an air gap.

### CROSS-REFERENCE TO RELATED APPLICATIONS

The present application claims priority under 35 U.S.C 119(a) to Korean Patent Application No. 10-2024-0118377, filed on Sep. 2, 2024, which is incorporated herein by reference in its entirety.

### BACKGROUND

### 1. Field

Various embodiments of the present disclosure relate to a semiconductor device, and more particularly, to a semiconductor device including three-dimensional (3D) memory cells, and a method for fabricating the semiconductor device.

### 2. Description of the Related Art

Recently, in order to cope with the trend of large capacity and miniaturization of a memory device, a three-dimensional (3D) memory device in which a plurality of memory cells are stacked has been proposed.

### SUMMARY

Embodiments of the present disclosure are directed to a semiconductor device including high-integrated memory cells, and a method for fabricating the semiconductor device.

In accordance with an embodiment of the present disclosure, a semiconductor device may include a plurality of nano sheets that are vertically stacked; a first conductive line coupled in common to first edges of the nano sheets, the first conductive line being oriented vertically; a plurality of data storage elements, each data storage element being coupled to second edges of the nano sheets; a plurality of second conductive lines, each second conductive line surrounding the nano sheets and being oriented horizontally; and a plurality of inter-cell dielectric layers disposed between the second conductive lines and each including an air gap.

In accordance with an embodiment of the present disclosure, a method for fabricating a semiconductor device may include forming nano sheet target layers that are vertically stacked and spaced apart from each other over a substrate; trimming first portions of the nano sheet target layers and forming flat plate-shaped sheets; forming a first spacer layer defining inner spaces in upper and lower portions of the flat plate-shaped sheets; forming air gap target layers that fill the inner spaces; forming strip barrier layers and strip paths between the strip barrier layers at entrances of the inner spaces; removing the air gap target layers through the strip paths and forming initial air gaps; forming air gap forming layers filling the initial air gaps and in which air gaps are embedded; horizontally recessing the first spacer layer to form a first spacer covering side surfaces of the air gap forming layers and surrounding recesses exposing the upper and lower portions of the flat plate-shaped sheets; and forming horizontal conductive lines filling the surrounding recesses and being disposed between the air gap forming layers.

In accordance with an embodiment of the present disclosure, a method for fabricating a semiconductor device may include forming nano sheet target layers that are vertically stacked and spaced apart from each other in a first direction over a substrate; trimming first portions of the nano sheet target layers and forming narrow sheets extending in a second direction that intersects the first direction; forming initial air gaps between the narrow sheets stacked in the first direction; forming air gap forming layers filling the initial air gaps and in which air gaps are embedded; forming surrounding recesses exposing the narrow sheets in a third direction that intersect the first and second directions, between the air gap forming layers; and forming horizontal conductive lines filling the surrounding recesses in the third direction and being disposed between the air gap forming layers.

These and other features and advantages of the embodiments of the present disclosure will become better understood by those with ordinary skill in the art from the following drawings and detailed description.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view of the memory cell illustrated in FIG. 1A.

FIG. 2A is a schematic perspective view illustrating a semiconductor device in accordance with an embodiment of the present disclosure.

FIG. 2B is a schematic perspective view of a memory cell array illustrated in FIG. 2A.

FIG. 2C is an equivalent circuit view of a column array illustrated in FIG. 2B.

FIG. 2D is an equivalent circuit view of a row array illustrated in FIG. 2B.

FIG. 3 is a schematic plan view illustrating a semiconductor device in accordance with an embodiment of the present disclosure.

FIG. 4A is a cross-sectional view of the semiconductor device taken along line A-A′ illustrated in FIG. 3.

FIG. 4B is a cross-sectional view of the semiconductor device taken along line B-B′ illustrated in FIG. 3.

FIGS. 5A to 26B illustrate various views of a semiconductor device formed utilizing a method for fabricating the semiconductor device in accordance with an embodiment of the present disclosure.

FIGS. 27 and 28 are schematic cross-sectional views of a semiconductor device in accordance with embodiments of the present disclosure.

FIGS. 29 and 30 illustrate a stack assembly in accordance with embodiments of the present disclosure.

### DETAILED DESCRIPTION

Various embodiments of the present disclosure may be described herein with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the embodiments of the present disclosure.

The following embodiments relate to three-dimensional (3D) memory cells with memory cells vertically stacked for increasing the memory cell density and reducing parasitic capacitance.

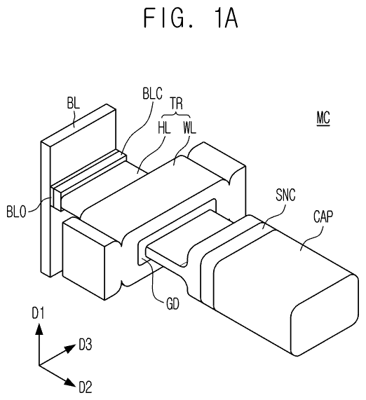

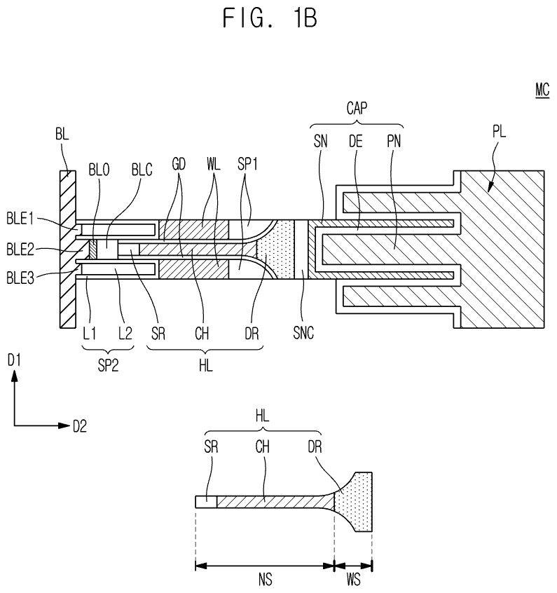

FIG. 1A is a schematic perspective view illustrating a memory cell MC in accordance with an embodiment of the present disclosure. FIG. 1B is a schematic cross-sectional view of the memory cell MC illustrated in FIG. 1A.

Referring to FIGS. 1A and 1B, the memory cell MC may include a first conductive line BL, a switching element TR, and a data storage element CAP.

The first conductive line BL may be vertically oriented in a first direction D1. The first conductive line BL may include a bit line. The first conductive line BL may be referred to as a “vertical conductive line”, a “vertically-oriented bit line”, a “vertically-extending bit line”, or a “pillar-shaped bit line”. The first conductive line BL may include a conductive material. The first conductive line BL may include a silicon-based material, a metal-based material, or a combination thereof. The first conductive line BL may include polysilicon, metal, metal nitride, metal silicide, or a combination thereof. The first conductive line BL may include polysilicon, titanium nitride, tungsten, or a combination thereof. For example, the first conductive line BL may include a titanium nitride/tungsten (TiN/W) stack in which titanium nitride and tungsten are sequentially stacked.

The switching element TR controls the voltage or current supply to the data storage element CAP during a data write or read operation performed onto the data storage element CAP. The switching element TR may include a nano sheet HL, a nano sheet dielectric layer GD, and a second conductive line WL. The second conductive line WL may include a horizontal conductive line or a horizontal word line, and the nano sheet HL may include an active layer. The switching element TR may include a transistor, and in this case, the second conductive line WL may serve as a gate electrode. The switching element TR may also be referred to as a “nano sheet transistor”, an “access element” or a “selection element”. The second conductive line WL may be referred to as a “horizontal gate electrode” or a “horizontal word line”.

The nano sheet HL may extend in a second direction D2 that intersects the first direction D1. The second conductive line WL may extend in a third direction D3 that intersects the first direction D1 and the second direction D2. The first direction D1 may be a vertical direction, the second direction D2 may be a first horizontal direction, and the third direction D3 may be a second horizontal direction. The nano sheet HL may extend in the first horizontal direction, i.e., the second direction D2, and the second conductive line WL may extend in the second horizontal direction, i.e., the third direction D3. The nano sheet HL may be referred to as a “horizontal layer”.

The nano sheet HL may include a channel CH, a first doped region SR between the channel CH and the first conductive line BL, and a second doped region DR between the channel CH and the data storage element CAP. The first doped region SR may be electrically coupled to the first conductive line BL, and the second doped region DR may be electrically coupled to the data storage element CAP. A height of the second doped region DR in the first direction D1 may be greater than the height of the first doped region SR and the channel CH in the first direction D1. A length of the second doped region DR in the second direction D2 may be less than that of the channel CH in the second direction D2. Lengths of the first doped region SR, the channel CH and the second doped region DR in the third direction D3 may be equal to one another.

The nano sheet HL may include a first region NS and a second region WS that are horizontally disposed adjacent to each other in the second direction D2. The second region WS may extend continuously without any gap from the first region NS. The second region WS may have a thickness that gradually increases in the second direction D2 from the first region NS toward the data storage element CAP between the first region NS and the data storage element CAP. An average vertical height or thickness of the second region WS in the first direction D1 may be greater than that of the first region NS. Hereinafter, the first region NS is referred to as a “narrow sheet”, and the second region WS is referred to as a “wide sheet”.

The narrow sheet NS may have a flat plate shape. The wide sheet WS may have a fan-like shape. The wide sheet WS may have a thickness that gradually increases in the second direction D2. The narrow sheet NS may be referred to as a “flat plate-shaped sheet”, and the wide sheet WS may be referred to as a “fan-like shaped sheet”. A boundary portion between the narrow sheet NS and the wide sheet WS may have a curvature.

The first doped region SR and the channel CH may be disposed in the narrow sheet NS, while the second doped region DR may be disposed in the wide sheet WS. The channel CH formed in the narrow sheet NS may be referred to as a “narrow channel” or a “flat channel”. One side of the wide sheet WS contacting the data storage element CAP and one side of the second doped region DR may each have a flat side shape.

In some embodiments, a portion of the second doped region DR may extend to be disposed in the narrow sheet NS. The second doped region DR may include a thick portion disposed in the wide sheet WS and a thin portion disposed in the narrow sheet NS.

A horizontal length of the wide sheet WS in the second direction D2 may be less than that of the narrow sheet NS, hence, the narrow sheet NS may be referred to as a “long sheet”, and the wide sheet WS may be referred to as a “short sheet”.

The nano sheet HL may include a semiconductive material. For example, the nano sheet HL may include polysilicon, monocrystalline silicon, germanium, or silicon-germanium. In some embodiments, the nano sheet HL may include an oxide semiconductor material. For example, the oxide semiconductor material may include indium gallium zinc oxide (IGZO), InSnZnO, ZnSnO, or a combination thereof. In some embodiments, the nano sheet HL may include a conductive metal oxide. In some embodiments, the nano sheet HL may include a two-dimensional material, for example, at least one of molybdenum disulfide (MoS₂), tungsten disulfide (WS₂) or molybdenum diselenide (MoSe₂).

When the nano sheet HL is formed of the oxide semiconductor material, the channel CH may also be formed of oxide semiconductor material, and the first and second doped regions SR and DR may be omitted. The nano sheet HL may also be referred to as an “active layer” or a “thin body”.

The first doped region SR and the second doped region DR may be doped with the same conductivity type of impurities. The first doped region SR and the second doped region DR may be doped with an N-type conductive impurity or a P-type conductive impurity. The first doped region SR and the second doped region DR may include at least one impurity selected from among arsenic (As), phosphorus (P), boron (B), indium (In), and combinations thereof. The first doped region SR may be electrically coupled to the first conductive line BL, and the second doped region DR may be electrically coupled to the data storage element CAP. The first and second doped regions SR and DR may be referred to as “first and second source/drain regions”.

The nano sheet HL may be horizontally oriented in the second direction D2 from the first conductive line BL.

The second conductive line WL may have a gate all around (GAA) structure. For example, the second conductive line WL may surround the nano sheet HL and extend in the third direction D3. The nano sheet dielectric layer GD may be formed between the nano sheet HL and the second conductive line WL. The nano sheet dielectric layer GD may surround a portion of the nano sheet HL, for example, the channel CH of the nano sheet HL. The second conductive line WL may surround the nano sheet HL on the nano sheet dielectric layer GD. The switching element TR may include a GAA transistor.

The second conductive line WL may include a metal-based material, a semiconductive material, or a combination thereof. The second conductive line WL may include molybdenum, molybdenum nitride, ruthenium, titanium nitride, tungsten, polysilicon, or a combination thereof. For example, the second conductive line WL may include a TiN/W stack in which titanium nitride and tungsten are sequentially stacked. The second conductive line WL may include an N-type work function material or a P-type work function material. The N-type work function material may have a low work function of approximately 4.5 eV or lower, and the P-type work function material may have a high work function of approximately 4.5 eV or higher. The second conductive line WL may include a stack of the low work function material and the high work function material.

The nano sheet dielectric layer GD may be disposed between the nano sheet HL and the second conductive line WL. The nano sheet dielectric layer GD may be referred to as a “gate dielectric layer” or a “channel-side dielectric layer”. The nano sheet dielectric layer GD may include silicon oxide, silicon nitride, metal oxide, metal oxide nitride, metal silicate, a high-k material, a ferroelectric material, an anti-ferroelectric material, or a combination thereof. The nano sheet dielectric layer GD may include SiO₂, Si₃N₄, HfO₂, Al₂O₃, ZrO₂, AlON, HfON, HfSiO, HfSiON, HfZrO, or a combination thereof. The nano sheet dielectric layer GD may be formed by a combination of deposition of a nano sheet dielectric material and thermal oxidation of the nano sheet HL. In some embodiments, the nano sheet dielectric layer GD may be deposited on the nano sheet HL or be formed by the thermal oxidation of the nano sheet HL.

The data storage element CAP may include a memory element for storing data. The data storage element CAP may, for example, be a capacitor. The data storage element CAP may be horizontally disposed in the second direction D2 from the switching element TR. The data storage element CAP may include a first electrode SN, a second electrode PN on the first electrode SN, and a dielectric layer DE between the first electrode SN and the second electrode PN. The first electrode SN may horizontally extend from the nano sheet HL in the second direction D2. The first electrode SN, the dielectric layer DE and the second electrode PN may be horizontally disposed in the second direction D2. The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may vertically extend in the first direction D1, and the horizontal outer surfaces of the first electrode SN may horizontally extend in the second direction D2 or the third direction D3. The inner space of the first electrode SN may be a three-dimensional space. The dielectric layer DE may conformally cover the inner and outer surfaces of the first electrode SN. The second electrode PN may be disposed in the inner space of the first electrode SN on the dielectric layer DE. Some of the outer surfaces of the first electrode SN may be electrically coupled to the second doped region DR of the nano sheet HL. The second electrode PN of the data storage element CAP may be coupled to a common plate PL. The first electrode SN may be referred to as a “storage node”.

The data storage element CAP may have a three-dimensional structure. The first electrode SN may have a three-dimensional structure, and the first electrode SN having the three-dimensional structure may have a three-dimensional structure that is horizontally oriented in the second direction D2. As an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically coupled to the second doped region DR of the nano sheet HL. The dielectric layer DE and the second electrode PN may be disposed on the cylindrical inner surfaces and cylindrical outer surfaces of the first electrode SN. In an embodiment, the first electrode SN may have a semi-cylindrical shape. Specifically, the semi-cylindrical shape may refer to a structure in which the second electrode PN partially covers the outer surfaces of the first electrode SN.

In some embodiments, the first electrode SN may have a concave shape, a pillar shape, or a pylinder shape. The pylinder shape may refer to a structure in which a pillar shape and a cylindrical shape are merged.

The first and second electrodes SN and PN may include metal, noble metal, metal nitride, conductive metal oxide, conductive noble metal oxide, metal carbide, metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TiN/W) stack, or a combination thereof. The second electrode PN may also include a combination of a metal-based material and a silicon-based material. For example, the second electrode PN may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material that fills the inside of the first electrode SN, titanium nitride (TiN) may serve as the second electrode PN of the data storage element CAP, and tungsten nitride may be a low-resistance material. In some embodiments, the second electrode PN may include a titanium nitride/tungsten/polysilicon (TiN/W/Poly-Si) stack.

The dielectric layer DE may be referred to as a “capacitor dielectric layer” or a “memory layer”. The dielectric layer DE may include silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In some embodiments, the dielectric layer DE may be formed of a composite layer including two or more layers of the above-described high-k material.

The dielectric layer DE may be formed of zirconium (Zr)-based oxide. The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃) and zirconium oxide (ZrO₂) are sequentially stacked. Each of the ZA stack and the ZAZ stack may be referred to as a “zirconium oxide (ZrO₂)-based layer”. In some embodiments, the dielectric layer DE may be formed of hafnium (Hf)-based oxide. The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃) and hafnium oxide (HfO₂) are sequentially stacked. Each of the HA stack and the HAH stack may be referred to as a “hafnium oxide (HfO₂)-based layer”. In the ZA stack, the ZAZ stack, the HA stack and the HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material having a greater band gap energy than the high-k material. The dielectric layer DE may include silicon oxide (SiO₂) as a high band gap material other than aluminum oxide (Al₂O₃). Since the dielectric layer DE includes a high band gap material, leakage current may be suppressed. The high band gap material may be thinner than the high-k material. In some embodiments, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH(HfO₂/ZrO₂/Al₂O₃/ZrO₂/HfO₂) stack, a ZHZAZHZ(ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA(Al₂O₃/HfO₂/ZrO₂/Al₂O₃/ZrO₂/HfO₂/Al₂O₃) stack. In the above-described stack structures, an aluminum oxide (Al₂O₃) layer may be thinner than zirconium oxide (ZrO₂) and hafnium oxide (HfO₂) layers.

In some embodiments, the dielectric layer DE may include a high-k material and a high band gap material, and the dielectric layer DE may have a laminated structure in which a plurality of high-k materials and a plurality of high band gap materials are stacked, or an intermixed structure in which a high-k material and a high band gap material are intermixed.

In some embodiments, the dielectric layer DE may include a ferroelectric material, an anti-ferroelectric material, or a combination thereof. For example, the dielectric layer DE may include HfZrO.

In some embodiments, the dielectric layer DE may include a combination of a high-k material and a ferroelectric material, a combination of a high-k material and an anti-ferroelectric material, or a combination of a high-k material or a ferroelectric material and an anti-ferroelectric material.

In some embodiments, an interface control layer (Not shown) may be further formed between the first electrode SN and the dielectric layer DE to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced with another data storage material. For example, the data storage material may be a thyristor, a phase-change material, a Magnetic Tunnel Junction (MTJ), or a variable resistance material.

The memory cell MC may further include a first contact node BLC and a second contact node SNC. The first contact node BLC may be disposed between the first conductive line BL and the nano sheet HL. The first contact node BLC may include a metal-based material or a semiconductive material. For example, the first contact node BLC may include titanium, titanium nitride, tungsten, or a combination thereof. In addition, the first contact node BLC may include doped polysilicon, and the first doped region SR may include an impurity diffused from the first contact node BLC. The second contact node SNC may be disposed between the nano sheet HL and the first electrode SN. The second contact node SNC may include a metal-based material or a semiconductive material. For example, the second contact node SNC may include titanium, titanium nitride, tungsten, or a combination thereof. In addition, the second contact node SNC may include doped silicon, and the second doped region DR may include an impurity diffused from the second contact node SNC. A height of the first contact node BLC in the first direction D1 may be less than that of the second contact node SNC in the first direction D1. The height of the first contact node BLC in the first direction D1 may be greater than that of the channel CH in the first direction D1.

In some embodiments, the second contact node SNC may be selectively grown from the wide sheet WS of the nano sheet HL. The second contact node SNC may be formed by selective epitaxial growth (SEG). For example, the second contact node SNC may be a silicon epitaxial layer formed by the selective epitaxial growth (SEG). The second contact node SNC may be a doped silicon epitaxial layer.

In some embodiments, the first contact node BLC may also be selectively grown from the narrow sheet NS of the nano sheet HL. The first contact node BLC may be formed by the selective epitaxial growth (SEG). For example, the first contact node BLC may be a silicon epitaxial layer formed by the selective epitaxial growth (SEG). The first contact node BLC may be a doped silicon epitaxial layer.

The first contact node BLC may be a narrow sheet-side contact node, and the second contact node SNC may be a wide sheet-side contact node.

The nano sheet HL may include a first edge and a second edge. The first edge may refer to a portion of the first doped region SR electrically coupled to the first conductive line BL, and the second edge may refer to a portion of the second doped region DR electrically coupled to the first electrode SN of the data storage element CAP.

The memory cell MC may further include an ohmic contact layer BLO between the first contact node BLC and the first conductive line BL. The ohmic contact layer BLO may include metal silicide. In some embodiments, the memory cell MC may further include an ohmic contact layer formed between the second contact node SNC and the first electrode SN of the data storage element CAP. The first conductive line BL, the ohmic contact layer BLO, the first contact node BLC and the first doped region SR may be electrically coupled to one another. The second doped region DR, the second contact node SNC and the first electrode SN of the data storage element CAP may be electrically coupled to one another.

The memory cell MC may further include a first spacer SP1 and a second spacer SP2. The first spacer SP1 may be disposed between the second conductive line WL and the second doped region DR. The second spacer SP2 may be disposed between the first conductive line BL and the second conductive line WL. The first and second spacers SP1 and SP2 may extend in the third direction D3 while surrounding the nano sheet HL. That is, the first and second spacers SP1 and SP2 may surround the nano sheet HL while being disposed on both sidewalls of the second conductive line WL.

The first spacer SP1 and the second spacer SP2 may have a double liner structure or a single liner structure. For example, the first spacer SP1 may have the single liner structure, the second spacer SP2 may have the double liner structure, and the double liner structure of the second spacer SP2 may include a stack of a first liner L1 and a second liner L2. The first and second spacers SP1 and SP2 may include a dielectric material. The first and second spacers SP1 and SP2 may include silicon oxide, silicon nitride, or a combination thereof. The first liner L1 of the second spacer SP2 may include silicon nitride, and the second liner L2 of the second spacer SP2 may include silicon oxide.

The first conductive line BL may include a plurality of horizontal extension portions BLE1, BLE2 and BLE3. The horizontal extension portions BLE1, BLE2 and BLE3 may extend in the second direction D2. The horizontal extension portions BLE1, BLE2 and BLE3 may include an inner horizontal extension portion BLE2 and outer horizontal extension portions BLE1 and BLE3. The inner horizontal extension portion BLE2 of the first conductive line BL may be disposed in a recess defined in the first liners L1 of the second spacers SP2 disposed vertically adjacent to each other. Accordingly, the inner horizontal extension portion BLE2 of the first conductive line BL may be electrically coupled to the ohmic contact layer BLO.

The outer horizontal extension portions BLE1 and BLE3 of the first conductive line BL may extend to be disposed in one side of the second spacer SP2. Accordingly, the outer horizontal extension portions BLE1 and BLE3 may contact the first and second liners L1 and L2 of the second spacer SP2. In some embodiments, the outer horizontal extension portions BLE1 and BLE3 of the first conductive line BL may be omitted.

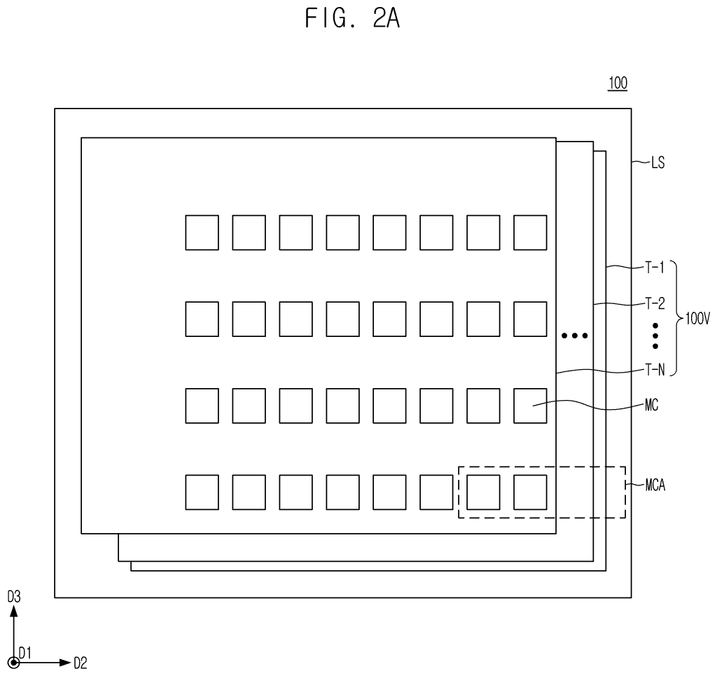

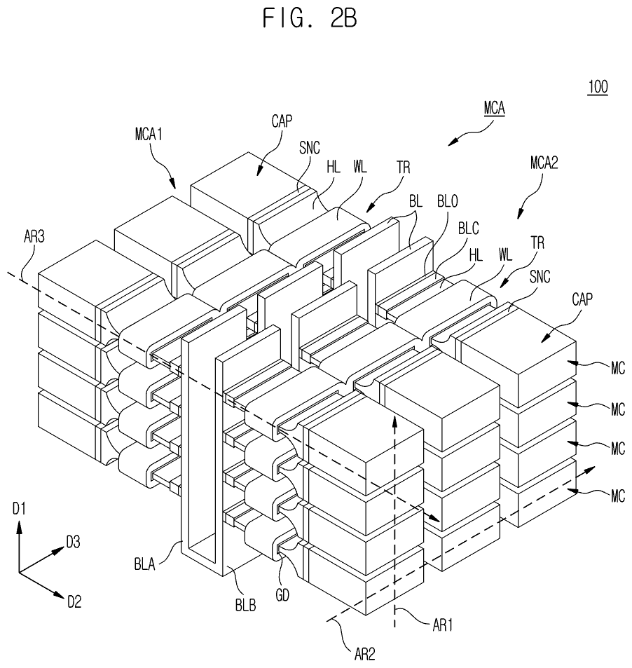

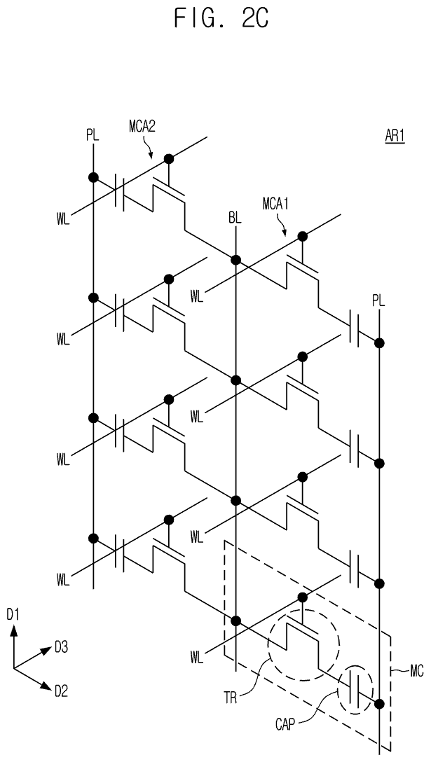

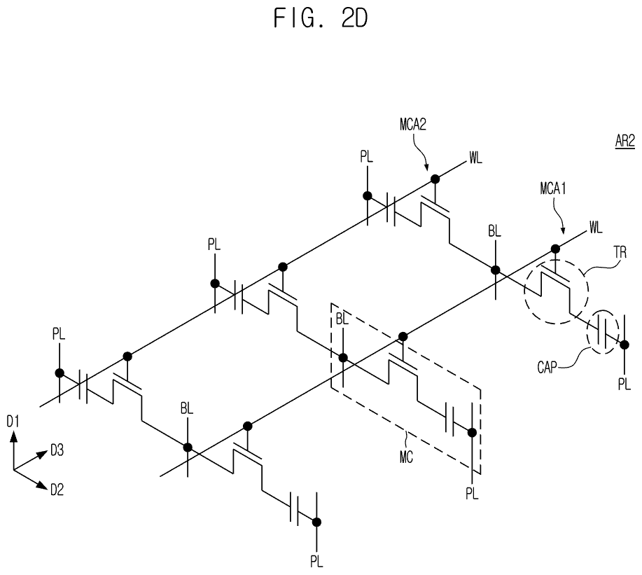

FIG. 2A is a schematic perspective view illustrating a semiconductor device 100 in accordance with an embodiment of the present disclosure. FIG. 2B is a schematic perspective view of memory cell array MCA illustrated in FIG. 2A. FIG. 2C is an equivalent circuit view of column array AR1 illustrated in FIG. 2B. FIG. 2D is an equivalent circuit view of row array AR2 illustrated in FIG. 2B.

Referring to FIGS. 2A to 2D, the semiconductor device 100 may include a plurality of planes T-1, T-2 and T-N constituting a vertical stack 100V. Each of the planes T-1, T-2 and T-N may include a plurality of memory cells MC. The vertical stack 100V may include the memory cell array MCA, and the memory cell array MCA may include a three-dimensional array of the memory cells MC. Detailed components of the memory cells MC are described above with reference to FIGS. 1A and 1B.

The memory cell array MCA may include a plurality of memory cells MC vertically stacked in a first direction D1, a plurality of memory cells MC horizontally disposed in a second direction D2, and a plurality of memory cells MC horizontally disposed in a third direction D3.

Each of the memory cells MC may include a first conductive line BL, a switching element TR, and a data storage element CAP. The switching element TR may include a second conductive line WL, a nano sheet dielectric layer GD, and a nano sheet HL extending between the first and second doped regions SR and DR. The memory cell MC may further include a first contact node BLC, an ohmic contact layer BLO, and a second contact node SNC. The memory cell MC may be the same as the memory cell MC illustrated in FIGS. 1A and 1B. As described with reference to FIGS. 1A and 1B, the second conductive line WL may have a gate all around (GAA) structure.

Although not illustrated, the memory cell MC may include first and second spacers described with reference to FIG. 1B. The first and second spacers may be disposed on both sides of each of the second conductive lines WL and extend in the third direction D3. The first and second spacers may extend in the third direction D3 while surrounding the nano sheets HL, similar to the second conductive lines WL.

The memory cell array MCA may include the column array AR1 of the memory cells MC and the row array AR2 of the memory cells MC. The column array AR1 may include the plurality of memory cells MC vertically stacked in the first direction D1. The memory cells MC in the column array AR1 may share the first conductive line BL. The row array AR2 may include the plurality of memory cells MC horizontally disposed in the third direction D3. The memory cells MC in the row array AR2 may share the second conductive line WL.

The column array AR1 may include a vertical arrangement of the nano sheets HL in the first direction D1, the first conductive line BL coupled in common to the nano sheets HL in the vertical arrangement, and the second conductive lines WL surrounding the nano sheets HL in the vertical arrangement.

The row array AR2 may include a horizontal arrangement of the nano sheets HL in the third direction D3, the first conductive lines BL coupled to the nano sheets HL in the horizontal arrangement, and the second conductive line WL surrounding the nano sheets HL in the horizontal arrangement.

The first direction D1 may be a vertical direction, and the third direction D3 may be a horizontal direction. The memory cell array MCA may further include a horizontal level array AR3, and the horizontal level array AR3 may include the plurality of memory cells MC disposed at the same horizontal level in the second direction D2. Neighboring memory cells MC of the horizontal level array AR3 may share the first conductive line BL.

The memory cell array MCA may include a first sub-cell array MCA1 and a second sub-cell array MCA2. The first sub-cell array MCA1 and the second sub-cell array MCA2 may each include a three-dimensional array of memory cells MC. The first and second sub-cell arrays MCA1 and MCA2 may share the first conductive line BL. The first conductive line BL may include a first vertical conductive line BLA and a second vertical conductive line BLB. A bottom portion of the first vertical conductive line BLA and a bottom portion of the second vertical conductive line BLB may be merged with each other to form a U-shape. Hence, the first conductive line BL may have a U-shape formed by the merging of the first and second vertical conductive lines BLA and BLB. The memory cells MC of the first sub-cell array MCA1 may share the first vertical conductive line BLA, while the memory cells MC of the second sub-cell array MCA2 may share the second vertical conductive line BLB. In this way, the neighboring first and second sub-cell arrays MCA1 and MCA2 may have a mirror-type structure sharing the first conductive line BL. From the perspective of a top view, the first and second vertical conductive lines BLA and BLB may each have a rectangular shape.

A lower structure LS may be disposed below the memory cell array MCA. The lower structure LS may include a semiconductor substrate, a metal interconnection structure, a dielectric structure, a conductive structure, a bonding pad structure, another memory, or a peripheral circuit portion. For example, the lower structure LS may include a structure in which the peripheral circuit portion, the metal interconnection structure and the bonding pad structure are sequentially stacked. The memory cell array MCA and the peripheral circuit portion of the lower structure LS may be bonded by wafer bonding.

The peripheral circuit portion of the lower structure LS may be disposed at a level lower than the memory cell array MCA. This may be referred to as a “cell over PERI (COP) structure”. The peripheral circuit portion may include at least one control circuit for driving the memory cell array MCA. At least one control circuit of the peripheral circuit portion may include an N-channel transistor, a P-channel transistor, a CMOS circuit, or a combination thereof. At least one control circuit of the peripheral circuit portion may include an address decoder circuit, a read circuit, or a write circuit. At least one control circuit of the peripheral circuit portion may include a planar channel transistor, a recess channel transistor, a buried gate transistor, or a fin channel transistor (FinFET).

For example, the peripheral circuit portion may include sub-word line drivers and a sense amplifier. The first conductive line BL may be coupled to the sense amplifier, and the second conductive lines WL may be coupled to the sub-word line drivers.

In some embodiments, the peripheral circuit portion may be disposed at a level higher than the memory cell array MCA. This may be referred to as a “PERI over cell (POC) structure”.

In some embodiments, the memory cell array MCA may include DRAM, embedded DRAM, NAND, FeRAM, STTRAM, PCRAM, or ReRAM.

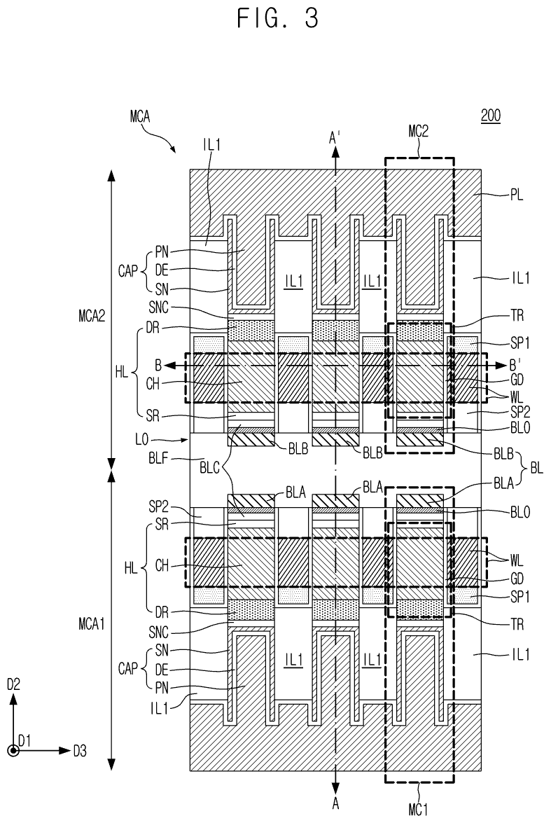

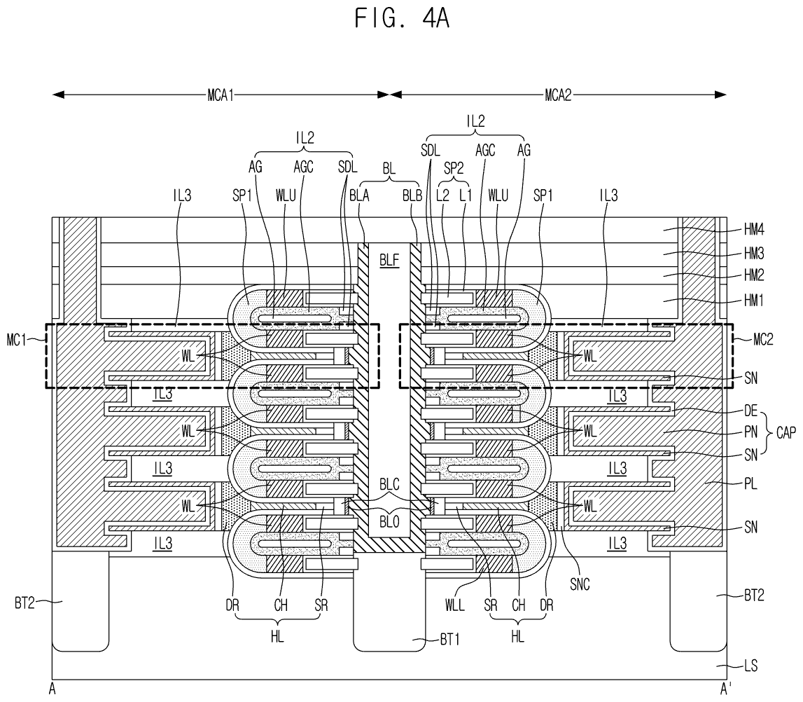

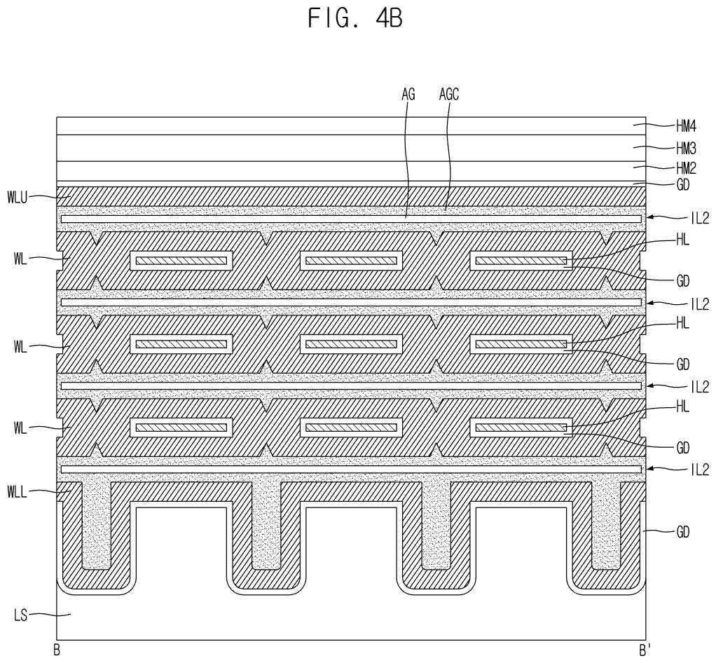

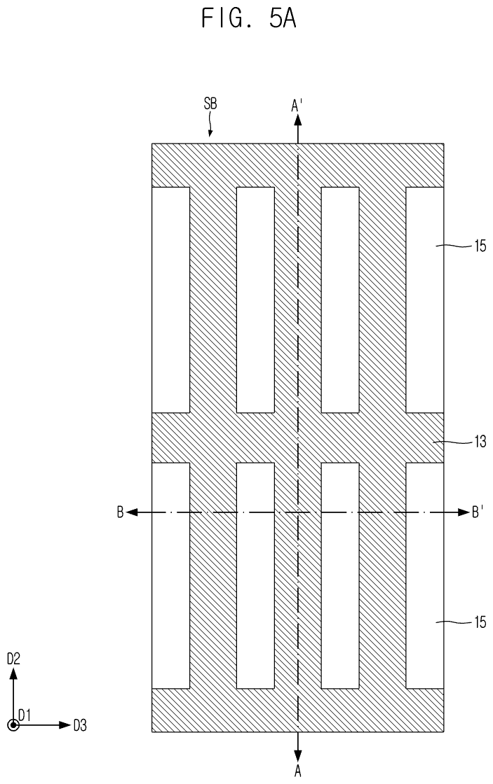

FIG. 3 is a schematic plan view illustrating a semiconductor device 200 in accordance with an embodiment of the present disclosure. FIG. 4A is a cross-sectional view of the semiconductor device 200 taken along line A-A′ illustrated in FIG. 3. FIG. 4B is a cross-sectional view of the semiconductor device 200 taken along line B-B′ illustrated in FIG. 3.

A memory cell array MCA of the semiconductor device 200 illustrated in FIGS. 3 to 4B may be similar to the memory cell array MCA illustrated in FIGS. 2A to 2D, and memory cells MC of the memory cell array MCA may be similar to the memory cell MC illustrated in FIGS. 1A and 1B. Detailed descriptions of overlapping components are provided above with reference to FIGS. 1A, 1B, 2A, 2B, 2C and 2D.

Referring to FIGS. 3, 4A and 4B, the semiconductor device 200 may include the memory cell array MCA, and a lower structure LS may be disposed below the memory cell array MCA. The memory cell array MCA may include a three-dimensional array of memory cells MC1 and MC2. The memory cell array MCA may include a first sub-cell array MCA1 and a second sub-cell array MCA2. The memory cell array MCA may include first conductive lines BL, and each of the first conductive lines BL may include a first vertical conductive line BLA and a second vertical conductive line BLB. A bottom portion of the first vertical conductive line BLA and a bottom portion of the second vertical conductive line BLB may be merged with each other. Each of the first conductive lines BL may have a U shape formed by the merging of the first vertical conductive line BLA and the second vertical conductive line BLB.

The first sub-cell array MCA1 may include a three-dimensional array of first memory cells MC1. Each of the first memory cells MC1 may include the first vertical conductive line BLA, a switching element TR, and a data storage element CAP, and the switching element TR may include a second conductive line WL and a nano sheet HL extending between the first and second doped regions SR and DR. The nano sheet HL may include a first doped region SR, a second doped region DR, and a channel CH. The second conductive line WL may surround the nano sheets HL at the same horizontal level disposed in a third direction D3. The second conductive line WL may surround the channels CH of the nano sheets HL at the same horizontal level disposed in the third direction D3. The first doped regions SR of the nano sheets HL may be electrically coupled to the first vertical conductive line BLA. The data storage element CAP may include a first electrode SN, a dielectric layer DE, and a second electrode PN. The second electrodes PN of the data storage elements CAP may be merged with each other to form a common plate PL. The second doped regions DR of the nano sheets HL may be electrically coupled to the first electrodes SN of the data storage elements CAP.

The second sub-cell array MCA2 may include a three-dimensional array of second memory cells MC2. Each of the second memory cells MC2 may include the second vertical conductive line BLB, a switching element TR, and a data storage element CAP, and the switching element TR may include a second conductive line WL and a nano sheet HL extending between the first and second doped regions SR and DR. The nano sheet HL may include a first doped region SR, a second doped region DR, and a channel CH. The second conductive line WL may surround the nano sheets HL at the same horizontal level disposed in the third direction D3. The first doped regions SR of the nano sheets HL may be electrically coupled to the second vertical conductive line BLB. The second conductive line WL may surround the channels CH of the nano sheets HL at the same horizontal level disposed in the third direction D3. The data storage element CAP may include a first electrode SN, a dielectric layer DE, and a second electrode PN. The second electrodes PN of the data storage elements CAP may be merged with each other to form a common plate PL. The second doped regions DR of the nano sheets HL may be electrically coupled to the first electrodes SN of the data storage elements CAP.

The first and second memory cells MC1 and MC2 may have the same configurations as the memory cells MC described with reference to FIGS. 1A, 1B, 2A, 2B, 2C and 2D.

The first and second vertical conductive lines BLA and BLB of the first and second sub-cell arrays MCA1 and MCA2 may vertically extend in a first direction D1, the nano sheets HL may extend in a second direction D2, and the second conductive lines WL may horizontally extend in the third direction D3.

The first memory cells MC1 of the first sub-cell array MCA1 vertically stacked in the first direction D1 may share the first vertical conductive line BLA, and the second memory cells MC2 of the second sub-cell array MCA2 vertically stacked in the first direction D1 may share the second vertical conductive line BLB.

Each of the first and second memory cells MC1 and MC2 of the first and second sub-cell arrays MCA1 and MCA2 may further include a first contact node BLC, an ohmic contact layer BLO, and a second contact node SNC.

The first contact node BLC may be disposed between each of the first conductive lines BLA and BLB and the nano sheet HL. The first contact node BLC may include a metal-based material or a semiconductive material. For example, the first contact node BLC may include titanium, titanium nitride, tungsten, or a combination thereof. In addition, the first contact node BLC may include doped polysilicon, and the first doped region SR may include an impurity diffused from the first contact node BLC.

The second contact node SNC may be disposed between the nano sheet HL and the first electrode SN. The second contact node SNC may include a metal-based material or a semiconductive material. For example, the second contact node SNC may include titanium, titanium nitride, tungsten, or a combination thereof. In addition, the second contact node SNC may include doped polysilicon, and the second doped region DR may include an impurity diffused from the second contact node SNC.

The height of the first contact node BLC in the first direction D1 may be less than that of the second contact node SNC in the first direction D1. The height of the first contact node BLC in the first direction D1 may be greater than that of the channel CH in the first direction D1.

The ohmic contact layer BLO may be formed between each of the first and second vertical conductive lines BLA and BLB and the first contact node BLC. The ohmic contact layer BLO may include metal silicide.

Each of the memory cells MC1 and MC2 may further include a first spacer SP1 and a second spacer SP2. The first and second spacers SP1 and SP2 may be disposed on both sides of the second conductive line. The first and second spacers SP1 and SP2 may extend in the third direction D3 while surrounding the nano sheets HL, similar to the second conductive lines WL. The first and second spacers SP1 and SP2 may extend in the third directions D3 while surrounding the nano sheets HL at the same horizontal level. The first spacer SP1 may have an integral structure extending vertically.

The first and second spacers SP1 and SP2 may each have a double liner structure or a single liner structure. For example, the first spacer SP1 may have the single liner structure, the second spacer SP2 may have the double liner structure, and the double liner structure of the second spacer SP2 may include a stack of a first liner L1 and a second liner L2. The first and second spacers SP1 and SP2 may include a dielectric material. The first and second spacers SP1 and SP2 may include silicon oxide, silicon nitride, or a combination thereof. The first liner L1 of the second spacer SP2 may include silicon nitride, and the second liner L2 of the second spacer SP2 may include silicon oxide.

Upper and lower surfaces of each of the second conductive lines WL may include a plurality of shallow concaves. That is, the upper and lower surfaces of each of the second conductive lines WL may not have a flat shape but may have a non-flat shape due to the plurality of shallow concaves.

First inter-cell dielectric layers IL1 may be formed between the memory cells MC disposed in the third direction D3. Second inter-cell dielectric layers IL2 may be formed between the memory cells MC stacked in the first direction D1. The first inter-cell dielectric layers IL1 may be disposed between the data storage elements CAP in the third direction D3. The second inter-cell dielectric layers IL2 may be disposed between the second conductive lines WL in the first direction D1. The second inter-cell dielectric layers IL2 may include a plurality of convexities. The convexities of the second inter-cell dielectric layers IL2 may be portions filled in the shallow concaves of the second conductive lines WL. Upper and lower surfaces of each of the second inter-cell dielectric layers IL2 may not have a flat shape but may have a non-flat shape due to the plurality of convexities. Among the second inter-cell dielectric layers IL2, an uppermost second inter-cell dielectric layer IL2 and a lowermost second inter-cell dielectric layer IL2 may include a combination of a flat shape and a non-flat shape. Third inter-cell dielectric layers IL3 may be formed between the data storage elements CAP stacked in the first direction D1. The third inter-cell dielectric layers IL3 may include silicon oxide. The third inter-cell dielectric layers IL3 may be disposed between the first electrodes SN of the data storage elements CAP in the first direction D1. The first spacer SP1 may cover one side of each of the second inter-cell dielectric layers IL2. The first spacer SP1 may have a cup shape, for example, a “D” shape.

The first to third inter-cell dielectric layers IL1, IL2 and IL3 may include silicon oxide, silicon carbon oxide, an air gap, an air gap-embedded oxide, or a combination thereof.

The first inter-cell dielectric layers IL1 may be referred to as a “vertical inter-cell dielectric layers”. The second inter-cell dielectric layers IL2 may be referred to as “first inter-cell horizontal dielectric layers”, and the third inter-cell dielectric layers IL3 may be referred to as “second inter-cell horizontal dielectric layers”.

Each of the second inter-cell dielectric layers IL2 may include an air gap AG. The second inter-cell dielectric layer IL2 may include a strip barrier layer SDL and an air gap forming layer AGC, and the air gap AG may be embedded in the air gap forming layer AGC. The strip barrier layer SDL may include silicon carbon oxide (SiOC). The air gap forming layer AGC may include silicon oxide. The strip barrier layer SDL may be a material selectively deposited on a surface of the first spacer SP1. The air gap forming layer AGC may be silicon oxide in which the air gap AG is embedded. Parasitic capacitance between the second conductive lines WL stacked in the first direction D1 may be reduced by the air gaps AG, and therefore, an RC (resistance-capacitance) delay may also be reduced. When the RC delay is reduced, a cell mat size may increase, thereby increasing cell density.

The memory cell array MCA may include a plurality of second conductive lines WL vertically stacked in the first direction D1. The memory cell array MCA may include a plurality of nano sheets HL vertically stacked in the first direction D1. The memory cell array MCA may include a plurality of data storage elements CAP vertically stacked in the first direction D1. The memory cell array MCA may include a plurality of first and second vertical conductive lines BLA and BLB spaced apart in the third direction D3.

The nano sheets HL of the switching elements TR horizontally disposed in the third direction D3 may share one second conductive line WL. The nano sheets HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line WL.

The memory cell array MCA may include dummy second conductive lines WLU and WLL disposed at a level higher than an uppermost second conductive line WL and at a level lower than a lowermost second conductive line WL, respectively. The dummy second conductive lines WLU and WLL may each have a linear shape extending horizontally.

The memory cell array MCA may include a stack of a plurality of hard mask layers HM1, HM2, HM3 and HM4 disposed at a level higher than the uppermost second conductive line WL.

The memory cell array MCA may include a plurality of first and second bottom protective layers BT1 and BT2. The first bottom protective layer BT1 may prevent electrical contact between a bottom surface of the first conductive line BL and the lower structure LS. The second bottom protective layer BT2 may prevent electrical contact between the data storage element CAP and the lower structure LS. The first bottom protective layer BT1 may be formed below the first and second vertical conductive lines BLA and BLB. The second bottom protective layer BT2 may be formed below the common plate PL. The first and second bottom protective layers BT1 and BT2 may include silicon oxide, silicon nitride, silicon carbon oxide, or a combination thereof.

A vertical isolation layer BLF may be disposed between the first and second vertical conductive lines BLA and BLB of the first conductive line BL. The vertical isolation layer BLF may include a dielectric material. The vertical isolation layer BLF may be disposed between the first vertical conductive lines BLA disposed in the third direction D3. The vertical isolation layer BLF may be disposed between the second vertical conductive lines BLB disposed in the third direction D3. The vertical isolation layer BLF may also be referred to as “a supporter,” and may serve to provide structural stability to the semiconductor device. The vertical isolation layer BLF may include silicon oxide, silicon nitride, an air gap, or a combination thereof.

The second electrodes PN of the data storage elements CAP may be coupled to the common plate PL.

According to the above-described embodiment, the semiconductor device 200 may include the vertically-stacked nano sheets HL, the vertically-oriented first conductive line BL coupled in common to first edges of the nano sheets HL, the data storage elements CAP coupled to second edges of the nano sheets HL, the horizontally-oriented second conductive lines WL surrounding the nano sheets HL, and the second inter-cell dielectric layers IL2 disposed between the second conductive lines WL and including the air gaps AG.

From another perspective, the semiconductor device 200 may include the column array and the row array of the nano sheets HL, the second conductive lines WL surrounding in common the nano sheets HL in the row array and surrounding the nano sheets HL in the column array, the air gaps AG disposed between the second conductive lines WL in the column array, the data storage elements CAP coupled to the nano sheets HL in the column array and the row array, and the first conductive line BL coupled in common to the nano sheets HL in the column array. The first conductive line BL may include the first vertical conductive line BLA and the second vertical conductive line BLB, and the first vertical conductive line BLA and the second vertical conductive line BLB may be formed through mask and etch processes.

From another perspective, the semiconductor device 200 may include the first sub-cell array MCA1 including the vertically-stacked first memory cells MC1, the second sub-cell array MCA2 including the vertically-stacked second memory cells MC2, a linear opening LO between the first sub-cell array MCA1 and the second sub-cell array MCA2, and the first conductive line BL formed in the linear opening LO and electrically coupled to the first and second memory cells MC1 and MC2 disposed horizontally adjacent to each other.

From another perspective, the semiconductor device 200 may include the first conductive line BL vertically oriented in the first direction D1, the data storage element CAP horizontally spaced apart from the first conductive line BL, the nano sheet HL horizontally oriented in the second direction D2 perpendicular to the first direction D1 and including a flat plate-shaped sheet NS contacting the first conductive line BL and a fan-shaped sheet WS contacting the data storage element CAP, and the second conductive line WL extending while surrounding the nano sheet HL in the third direction D3 perpendicular to the first and second directions D1 and D2.

From another perspective, the semiconductor device 200 may include a vertical stack including the column array AR1 of nano sheet transistors TR vertically stacked in the first direction D1, and the air gaps AG disposed between the nano sheet transistors TR in the column array AR1. Each of the nano sheet transistors TR may include the horizontal conductive line WL extending in the third direction D3 perpendicular to the first and second directions D1 and D2 while surrounding a flat plate-shaped sheet NS of the nano sheet HL extending in the second direction D2 perpendicular to the first direction D1. Herein, the nano sheet HL may include the flat plate-shaped sheet NS and a fan-shaped sheet WS having a shorter horizontal length than the flat plate-shaped sheet NS.

From another perspective, the semiconductor device 200 may include a first column array MCA1 of nano sheet transistors TR vertically stacked in the first direction D1, a second column array MCA2 of nano sheet transistors TR horizontally spaced apart from the first column array MCA1 and vertically stacked in the first direction D1, the vertical conductive line BL sharing the nano sheet transistors TR in the first column array MCA1 and the nano sheet transistors TR in the second column array MCA2 and extending in the first direction D1, and the data storage elements CAP coupled to the nano sheet transistors TR in the first and second column arrays MCA1 and MCA2. Each of the nano sheet transistors TR may include the horizontal conductive line WL extending in the third direction D3 perpendicular to the first and second directions D1 and D2 while surrounding a flat plate-shaped sheet NS of the nano sheet HL extending in the second direction D2 perpendicular to the first direction D1. Herein, the nano sheet HL may include the flat plate-shaped sheet NS and a fan-shaped sheet WS having a shorter horizontal length than the flat plate-shaped sheet NS. The horizontal conductive lines WL in the first and second column arrays MCA1 and MCA2 may extend in the third direction D3 while surrounding the nano sheets HL at the same horizontal level. Each of the air gaps AG may be disposed between the horizontal conductive lines WL in the first and second column arrays MCA1 and MCA2.

From another perspective, the semiconductor device 200 may include a vertical arrangement of nano sheet transistors TR each having a gate all around (GAA) structure and the air gaps AG disposed between vertical gaps in the vertical arrangement of the nano sheet transistors TR. Each of the nano sheet transistors TR may include the horizontal conductive line WL, and each of the air gaps may be disposed between the horizontal conductive lines WL.

From another perspective, the semiconductor device 200 may include a vertical arrangement of memory cells including nano sheet transistors TR each having a gate all around (GAA) structure and the air gaps AG disposed between vertical gaps in the vertical arrangement of the memory cells. Each of the nano sheet transistors TR may include the horizontal conductive line WL, and each of the air gaps may be disposed between the horizontal conductive lines WL.

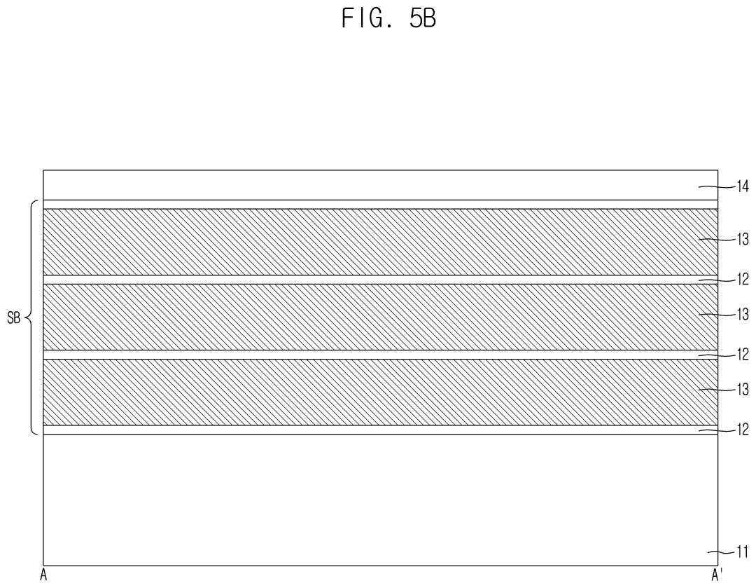

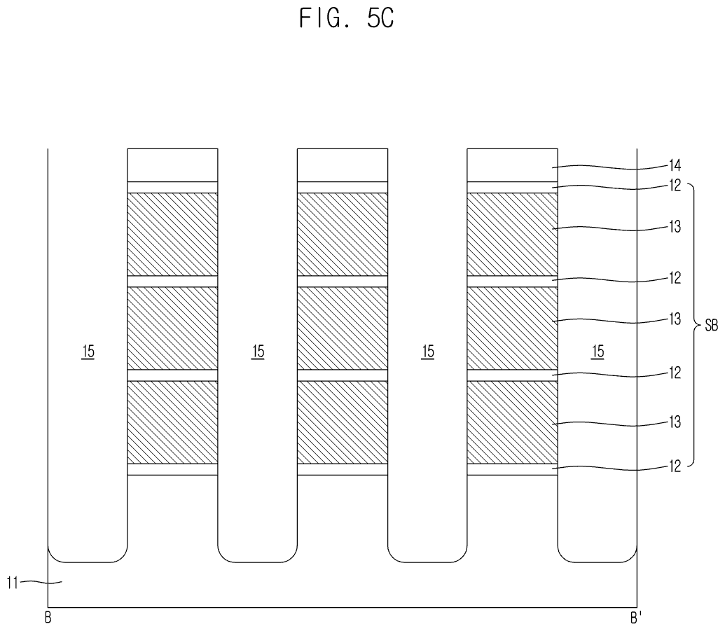

FIGS. 5A to 26B illustrate various views of a semiconductor device for illustrating a method for fabricating the semiconductor device in accordance with an embodiment of the present disclosure.

FIG. 5A is a plan view illustrating a structure at a second mold layer level for describing a method for forming a mold stack SB. FIG. 5B is a cross-sectional view of the structure taken along line A-A′ illustrated in FIG. 5A, and FIG. 5C is a cross-sectional view of the structure taken along line B-B′ illustrated in FIG. 5A.

As illustrated in FIGS. 5A to 5C, the mold stack SB may be formed on a substrate 11. The mold stack SB may include an alternating stack of first and second mold layers 12 and 13.

The first mold layers 12 and the second mold layers 13 may be epitaxially grown multiple times, to form the mold stack SB.

The first mold layers 12 and the second mold layers 13 may be made of different semiconductive materials. The first mold layers 12 may include silicon germanium or monocrystalline silicon germanium. The second mold layers 13 may include monocrystalline silicon. The first mold layers 12 and the second mold layers 13 may be formed by an epitaxial growth process. A lowermost first mold layer 12 may serve as a seed layer during the epitaxial growth process. The first mold layers 12 may be thinner than the second mold layers 13. The first mold layers 12 may include first epitaxially grown layers, and the second mold layers 13 may include second epitaxially grown layers.

In an embodiment, a plurality of silicon germanium layers may be alternately stacked with a plurality of monocrystalline silicon layers in the first mold stack SB. A stack of a silicon germanium layer/a monocrystalline silicon layer (SiGe/Si stack) may be stacked multiple times. The first mold layers 12 may be referred to as “sacrificial layers”, and the second mold layers 13 may be referred to as “nano sheet target layers” or “recess target layers”.

The mold stack SB may be referred to as a “vertical stack”. The mold stack SB may be formed by alternately stacking a plurality of sacrificial layers and a plurality of nano sheet target layers. The sacrificial layers may be silicon germanium layers, and the nano sheet target layers may be monocrystalline silicon layers.

A thickness ratio of the first mold layers 12 and the second mold layers 13 in the mold stack SB may be variously modified. For example, the thickness of each of the first mold layers 12 may be approximately 5 to 20 nm, and the thickness of each of the second mold layers 13 may be approximately 50 to 80 nm. A quantity of the first mold layers 12 and a quantity of the second mold layers 13 in the mold stack SB may be variously modified. In some embodiments, a triple stack including the first mold layer 12/the second mold layer 13/the third mold layer 12 may be defined at lowermost and uppermost portions of the mold stack SB. The second mold layer 13 of the triple stack may have a thinner thickness than another second mold layer 13.

A first hard mask layer 14 may be formed on the mold stack SB. The first hard mask layer 14 may include a dielectric material such as an oxide-based material, a nitride-based material, a carbon-based material, or a combination thereof. For example, the first hard mask layer 14 may include SiO₂, Si₃N₄, amorphous carbon, or a combination thereof.

Subsequently, referring to FIG. 5C, some portions of the mold stack SB may be etched using the first hard mask layer 14 as a barrier, and a plurality of sacrificial isolation openings 15 may be formed in the mold stack SB. The sacrificial isolation openings 15 may be initial openings for cell isolation. From the perspective of a top view, cross-sections of the sacrificial isolation openings 15 may each have a rectangular shape. In some embodiments, the cross-sections of the sacrificial isolation openings 15 may each have a circular shape or an oval shape. In some embodiments, the sacrificial isolation openings 15 may be referred to as “sacrificial isolation trenches”. The sacrificial isolation openings 15 may vertically extend in a first direction D1 and extend lengthwise in a second direction D2. The sacrificial isolation openings 15 may be disposed at a predetermined interval in a third direction D3. Bottom surfaces of the sacrificial isolation openings 15 may extend inside the substrate 11.

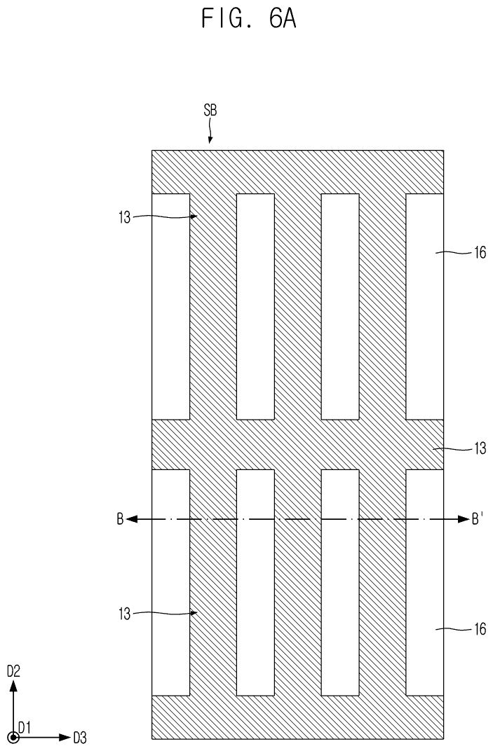

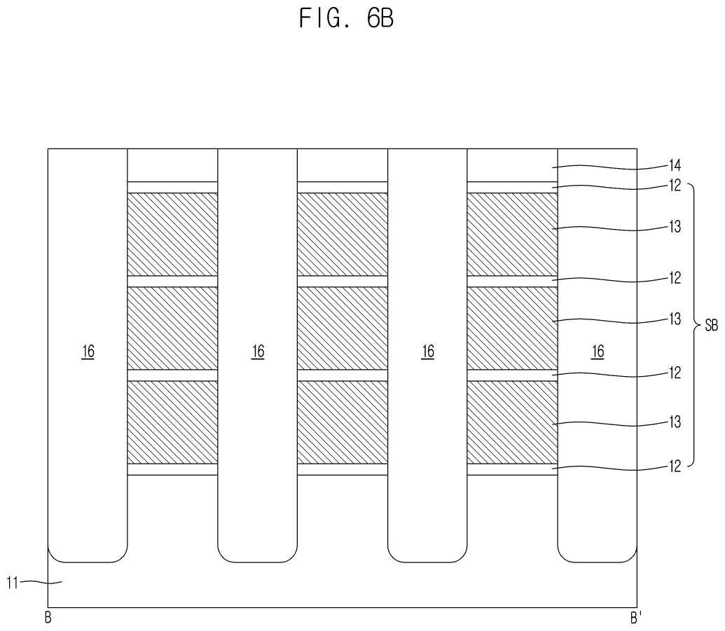

FIG. 6A is a plan view illustrating the structure at the second mold layer level for describing a method for forming sacrificial isolation layers 16, and FIG. 6B is a cross-sectional view of the structure taken along line B-B′ illustrated in FIG. 6A.

As illustrated in FIGS. 6A and 6B, the sacrificial isolation layers 16 may be formed to fill the sacrificial isolation openings 15. The sacrificial isolation layers 16 may include the same material. The sacrificial isolation layers 16 may be formed of a dielectric material. The sacrificial isolation layers 16 may have an etch selectivity with respect to the mold stack SB. For example, the sacrificial isolation layers 16 may each include silicon oxide, silicon nitride, silicon carbon oxide, silicon carbon nitride, or a combination thereof. Forming the sacrificial isolation layers 16 may include forming sacrificial isolation materials on the mold stack SB to fill the sacrificial isolation openings 15 and planarizing the sacrificial isolation materials so that a surface of the first hard mask layer 14 is exposed.

The sacrificial isolation layers 16 may vertically extend in the first direction D1 and extend lengthwise in the second direction D2. The sacrificial isolation layers 16 may be disposed at a predetermined interval in the third direction D3. Each of the sacrificial isolation layers 16 may include a stack of a first sacrificial liner layer and a first sacrificial gap-fill layer. The first sacrificial liner layer may be silicon nitride, and the first sacrificial gap-fill layer may be silicon oxide. The sacrificial isolation layers 16 may penetrate the mold stack SB in the first direction D1.

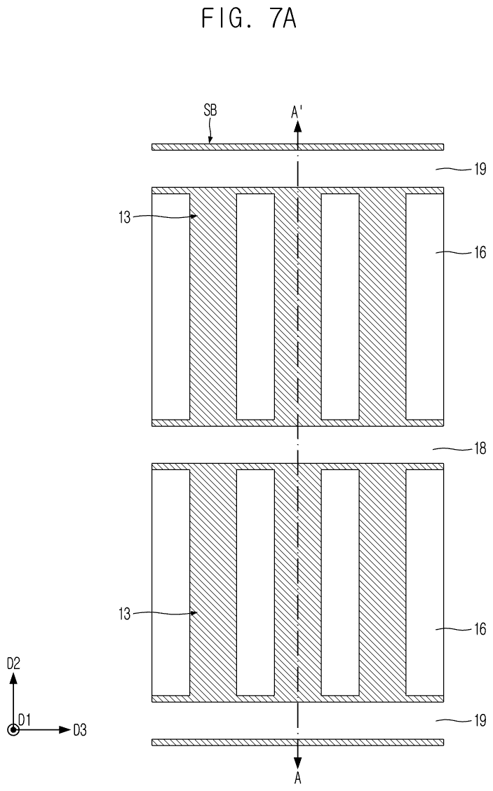

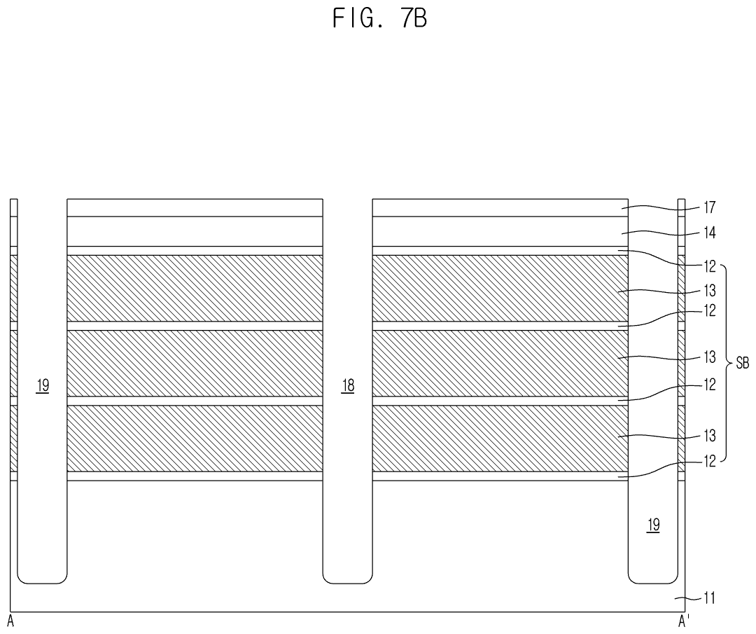

FIG. 7A is a plan view illustrating the structure at the second mold layer level for describing a method for forming sacrificial linear openings 18 and 19. FIG. 7B is a cross-sectional view illustrating the structure taken along line A-A′ illustrated in FIG. 7A.

As illustrated in FIGS. 7A and 7B, a second hard mask layer 17 may be formed on the mold stack SB and the sacrificial isolation layers 16. The second hard mask layer 17 may include silicon nitride. The second hard mask layer 17 may be formed by etching a second hard mask material using a mask layer such as photoresist. The second hard mask layer 17 may have a plurality of line-shaped openings defined therein.

Portions of the mold stack SB may be etched using the second hard mask layer 17 as an etch barrier. Accordingly, a plurality of sacrificial linear openings 18 and 19 may be formed between the sacrificial isolation layers 16. The sacrificial linear openings 18 and 19 may include a first sacrificial linear opening 18 and a second sacrificial linear opening 19. From the perspective of a top view, the first sacrificial linear opening 18 and the second sacrificial linear opening 19 may be line-shaped openings extending in the third direction D3. The first sacrificial linear opening 18 and the second sacrificial linear opening 19 may vertically extend in the first direction D1. The sacrificial isolation layers 16 may be disposed between the first sacrificial linear opening 18 and the second sacrificial linear opening 19 in the second direction D2. From the perspective of a top view, cross sections of the first and second sacrificial linear openings 18 and 19 may each have a rectangular shape. In some embodiments, the cross sections of the first and second sacrificial linear openings 18 and 19 may each have a circular shape or an oval shape. The first and second sacrificial linear openings 18 and 19 may each have a width in the second direction D2 less than a width in the third direction D3. The first and second sacrificial linear openings 18 and 19 may be referred to as “sacrificial linear trenches”. The sacrificial isolation layers 16 may not contact the first and second sacrificial linear openings 18 and 19.

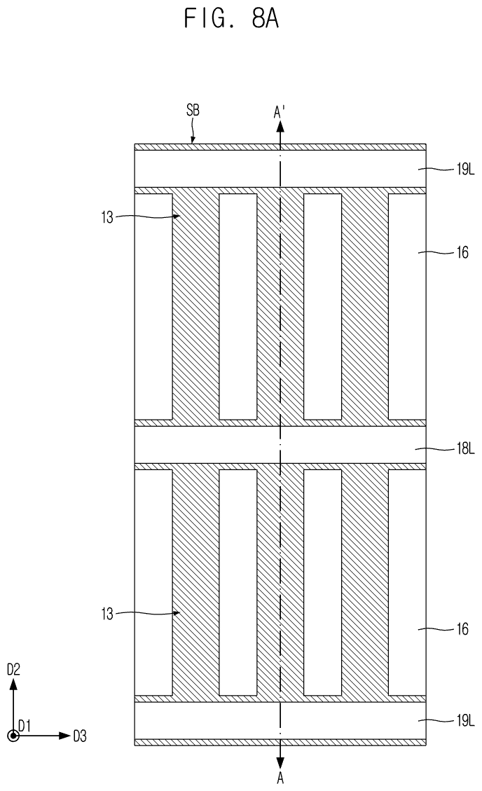

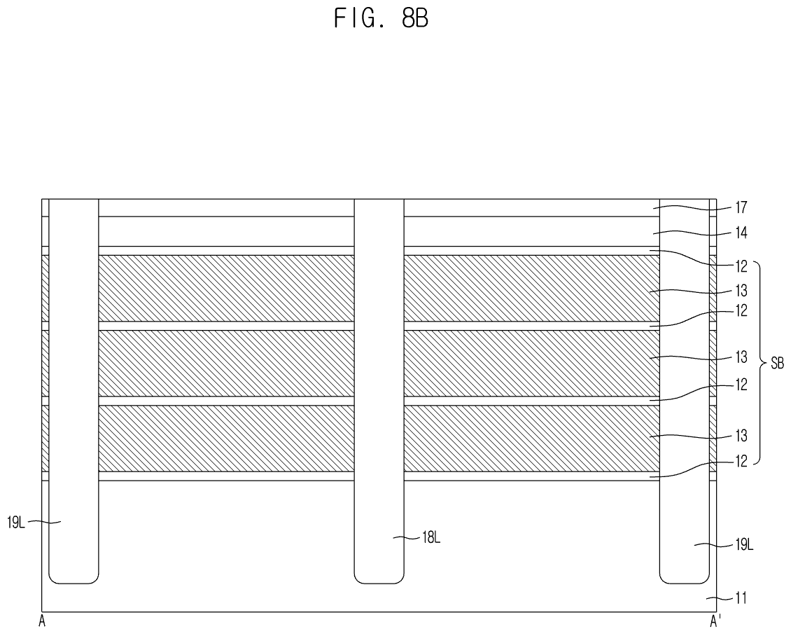

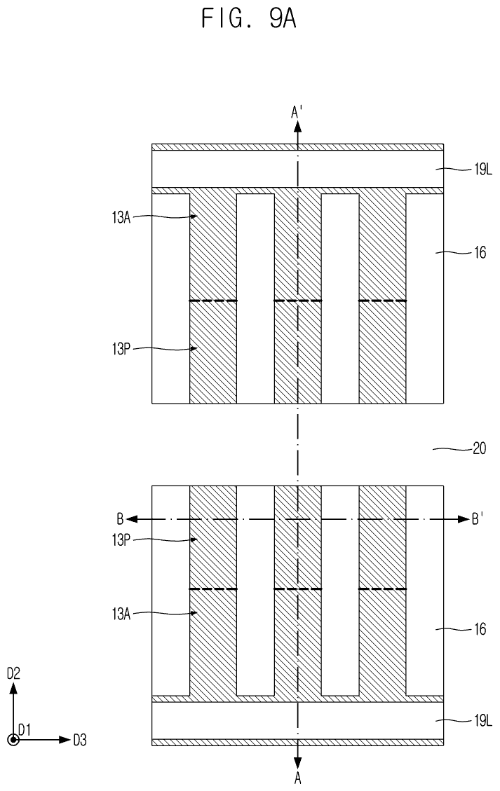

FIG. 8A is a plan view illustrating the structure at the second mold layer level for describing a method for forming linear sacrificial layers 18L and 19L, and FIG. 8B is a cross-sectional view illustrating the structure taken along line A-A′ illustrated in FIG. 8A.

As illustrated in FIGS. 8A and 8B, the linear sacrificial layers 18L and 19L may be formed to fill the sacrificial linear openings 18 and 19. The linear sacrificial layers 18L and 19L may include a first linear sacrificial layer 18L and a second linear sacrificial layer 19L. From the perspective of a top view, the first linear sacrificial layer 18L and the second linear sacrificial layer 19L may have line shapes extending in the third direction D3. The first linear sacrificial layer 18L and the second linear sacrificial layer 19L may vertically extend in the first direction D1. The sacrificial isolation layers 16 may be disposed between the first linear sacrificial layer 18L and the second linear sacrificial layer 19L in the second direction D2. From the perspective of a top view, cross sections of the first and second linear sacrificial layers 18L and 19L may each have a rectangular shape. In some embodiments, the cross-sections of the first and second linear sacrificial layers 18L and 19L may each have a circular shape or an oval shape. The first and second linear sacrificial layers 18L and 19L may include the same material. The first and second linear sacrificial layers 18L and 19L may be formed of a dielectric material. For example, the first and second linear sacrificial layers 18L and 19L may each include silicon oxide, silicon nitride, silicon carbon oxide, silicon carbon nitride, or a combination thereof. The sacrificial isolation layers 16 may not contact the first and second linear sacrificial layers 18L and 19L.

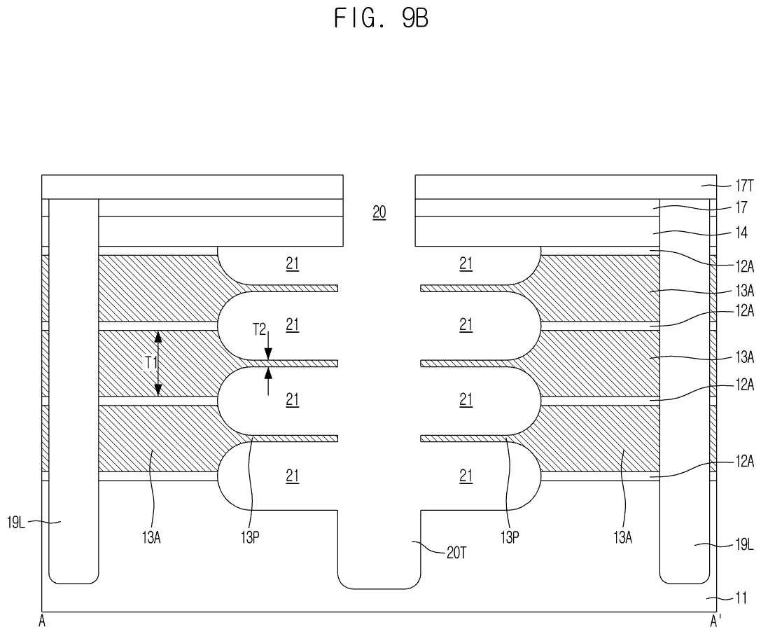

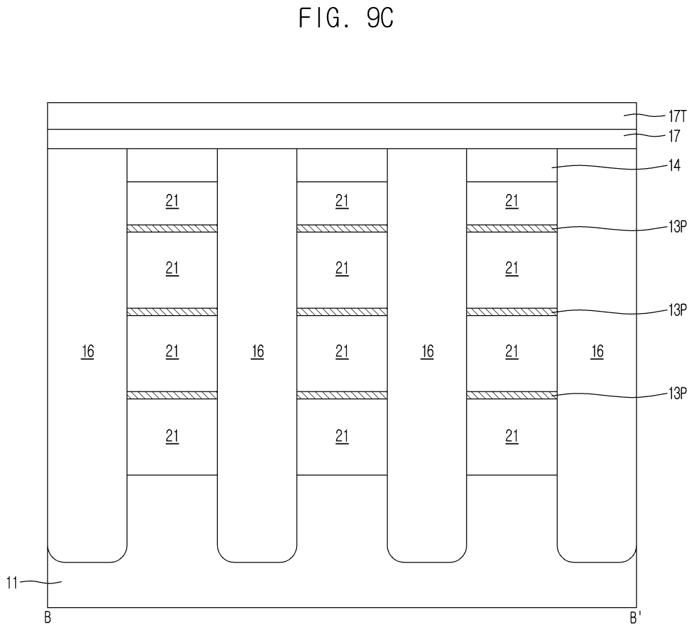

FIG. 9A is a plan view illustrating the structure at the second mold layer level for describing partial recessing of the first and second mold layers 12 and 13. FIG. 9B is a cross-sectional view illustrating the structure taken along line A-A′ illustrated in FIG. 9A. FIG. 9C is a cross-sectional view illustrating the structure taken along line B-B′ illustrated in FIG. 9A.

As illustrated in FIGS. 9A to 9C, among the first linear sacrificial layer 18L and the second linear sacrificial layer 19L, the first linear sacrificial layer 18L may be selectively removed. A third hard mask layer 17T may be used as an etch barrier to remove the first linear sacrificial layer 18L. Accordingly, a first linear opening 20 may be formed. From the perspective of a top view, as shown in FIG. 9A, the first linear opening 20 may be disposed horizontally spaced apart from the second linear sacrificial layer 19L in the second direction D2.

The first mold layers 12 may be selectively recessed through the first linear openings 20. A difference in etch selectivity between the first mold layers 12 and the second mold layers 13 may be used to selectively recess the first mold layers 12. The first mold layers 12 may be removed using a wet etch process or a dry etch process. For example, when the first mold layers 12 include silicon germanium layers and the second mold layers 13 include monocrystalline silicon layers, the silicon germanium layers may be etched using an etchant or etch gas having a selectivity with respect to the monocrystalline silicon layers. By the partial recessing of the first mold layers 12, the upper and lower surfaces of the second mold layers 13 may be partially exposed. A part of each of the first mold layers may remain and may have its original thickness as indicated by reference numeral “12A”.

Subsequently, an exposed portion (a first portion) of each of the second mold layers 13 may be selectively recessed leaving only a narrow sheet 13P. The wet etch process or dry etch process may be used to recess the second mold layers 13.

An original body portion 13A and the narrow sheet 13P may be formed by the partial recessing of each of the second mold layers 13. The original body portion 13A may maintain an original thickness T1, and the narrow sheet 13P may have a thickness T2 thinner than the original thickness T1. A horizontal length of the original body portion 13A in the second direction D2 may be equal to or different from a horizontal length of the narrow sheet 13P in the second direction D2. The combination of the original body portion 13A and the narrow sheet 13P may be referred to as a “preliminary nano sheet”. The narrow sheet 13P may be referred to as a “flat plate-shaped sheet” or a “protruding narrow sheet”.

The recessing process for forming the narrow sheet 13P may be referred to as a “thinning process” or “trimming process” of the second mold layer 13. To form the narrow sheet 13P, an upper surface, lower surface and side surface of the second mold layer 13 may be recessed. The narrow sheet 13P may be referred to as a “thin-body active layer”. The narrow sheet 13P may include a monocrystalline silicon layer. The recessing process for forming the narrow sheet 13P may use, for example, Hot SC-1 (HSC1). The HSC1 may include a solution in which ammonium hydroxide (NH₄OH), hydrogen peroxide (H₂O₂) and water (H₂O) are mixed in a ratio of 1:4:20. Using the HSC1, the second mold layers 13 may be selectively etched.

The narrow sheets 13P may be formed by the partial recessing process for the second mold layers 13 as described above, and an inter-nano sheet recess 20 may be formed between the narrow sheets 13P that are vertically disposed. Upper and lower surfaces of the narrow sheets 13P may each include a flat surface. A boundary portion between the original body portion 13A and the narrow sheet 13P may be vertical or have a curvature. Each of the first mold layers 12A may be disposed between the original body portions 13A that are vertically stacked. A horizontal arrangement of the narrow sheets 13P may be formed in the third direction D3. A vertical arrangement of the narrow sheets 13P may be formed in the first direction D1. Inter-nano sheet recesses 21 may be referred to as vertical gaps between the narrow sheets 13P in the vertical arrangement.

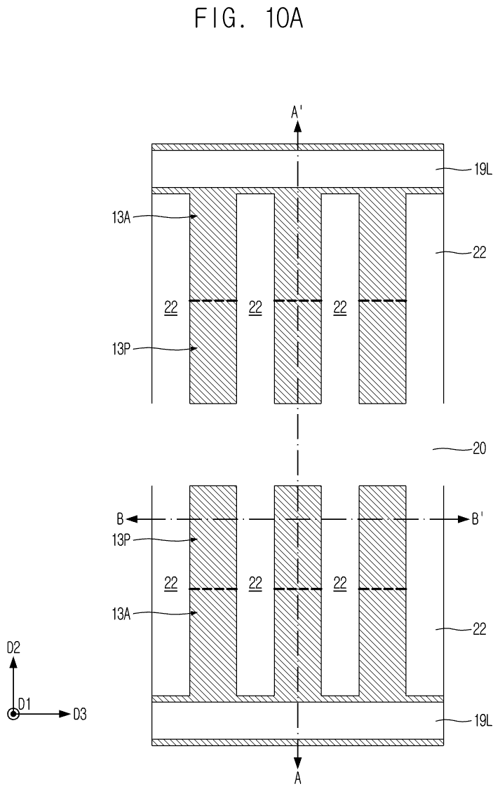

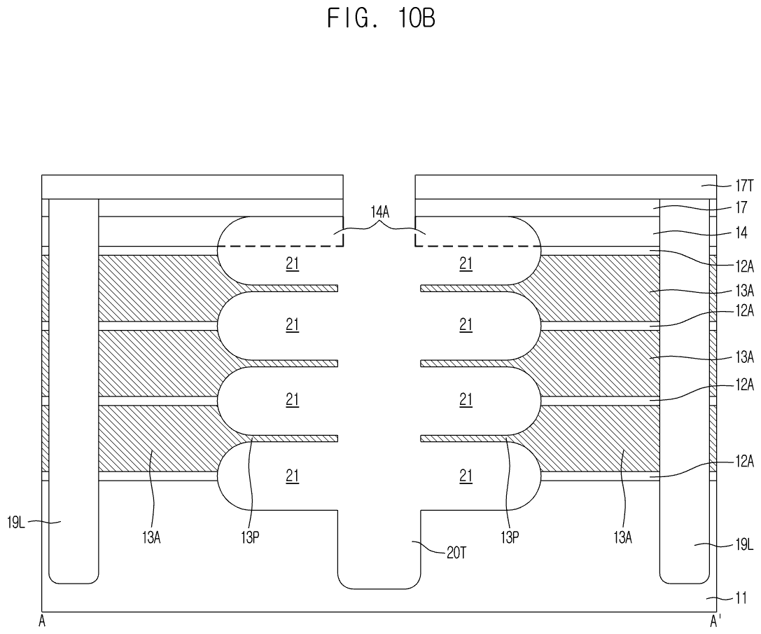

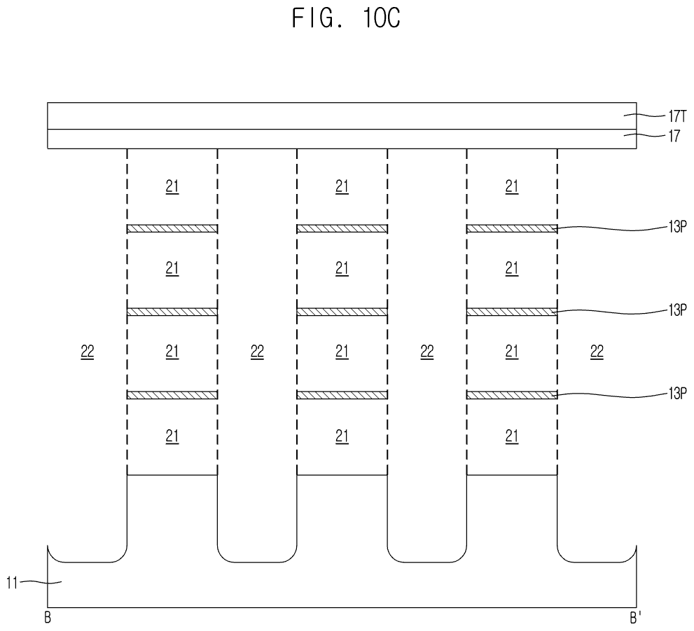

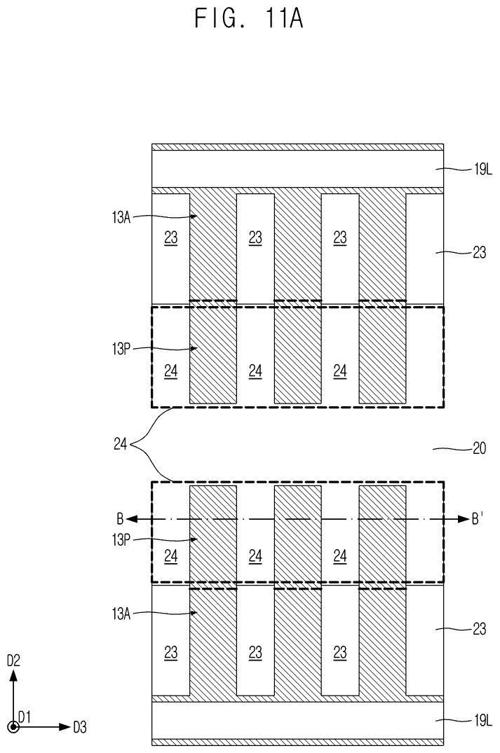

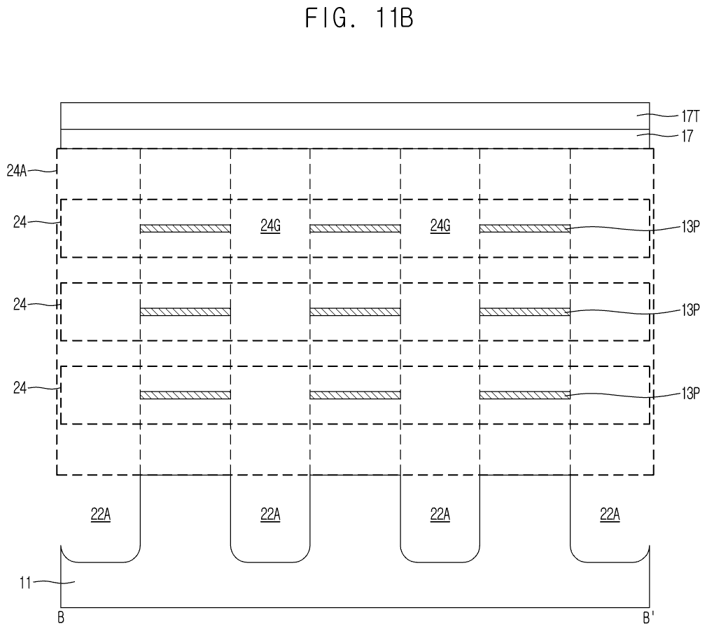

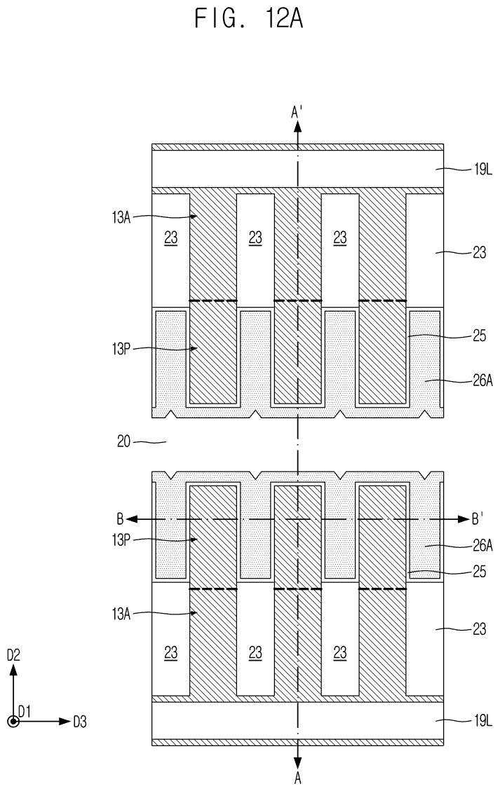

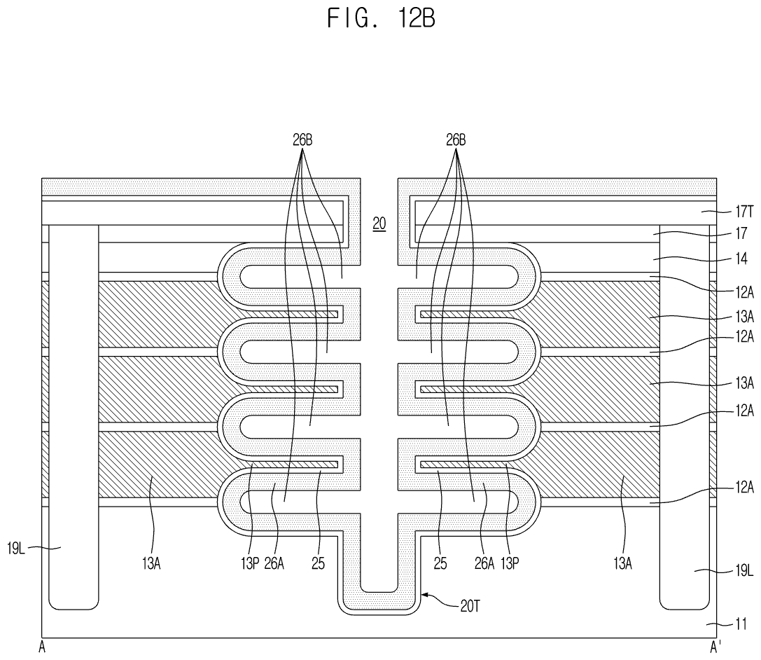

FIG. 10A is a plan view illustrating the structure at a narrow sheet level for describing a method for forming sacrificial isolation layer-level openings 22. FIG. 10B is a cross-sectional view illustrating the structure taken along line A-A′ illustrated in FIG. 10A. FIG. 10C is a cross-sectional view illustrating the structure taken along line B-B′ illustrated in FIG. 10A.

As illustrated in FIGS. 10A to 10C, the sacrificial isolation layers 16 may be selectively stripped through the inter-nano sheet recesses 21. Accordingly, each of the sacrificial isolation layer-level openings 22 may be formed between the original body portions 13A in the third direction D3.

Side surfaces of the first mold layers 12A, side surfaces of the original body portions 13A and side surfaces of the narrow sheets 13P may be exposed in the third direction D3 by the sacrificial isolation layer-level openings 22.

While the sacrificial isolation layer-level openings 22 are formed, a portion of the first hard mask layer 14 (refer to reference numeral “14A”) may be recessed. Accordingly, an uppermost inter-nano sheet recess 21 may be expanded.

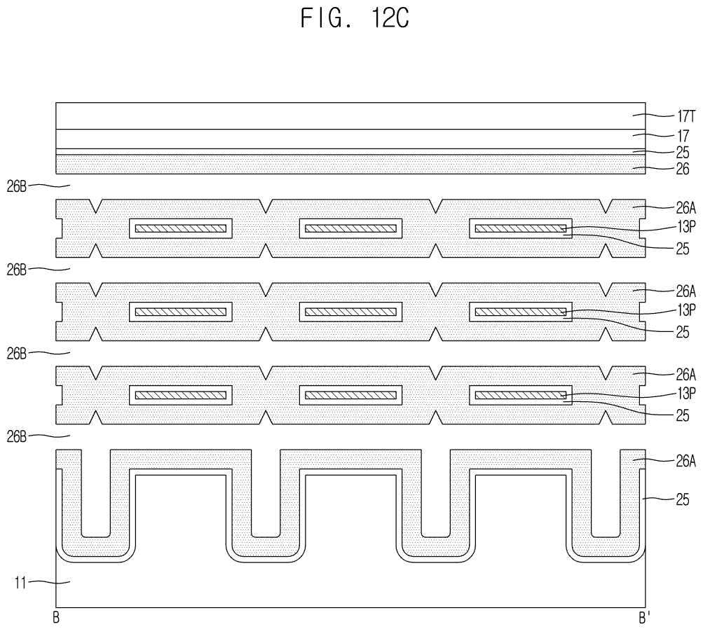

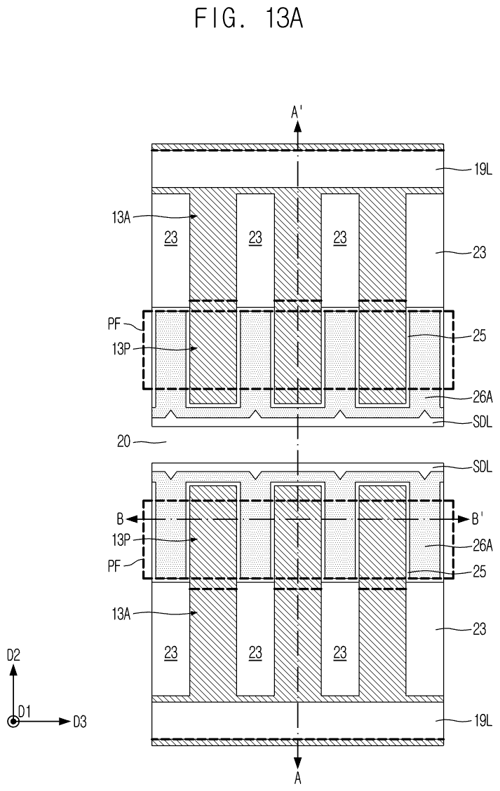

FIG. 11A is a plan view illustrating the structure at the narrow sheet level for describing a method for forming first inter-cell dielectric layers 23. FIG. 11B is a cross-sectional view illustrating the structure taken along line B-B′ illustrated in FIG. 11A.

As illustrated in FIGS. 11A and 11B, the first inter-cell dielectric layers 23 may be formed in the sacrificial isolation layer-level openings 22. The first inter-cell dielectric layers 23 may each include a dielectric material. The first inter-cell dielectric layers 23 may each include silicon oxide, silicon nitride, silicon carbon oxide, or a combination thereof. Forming the first inter-cell dielectric layers 23 may include forming a dielectric material that fills the sacrificial isolation layer-level openings 22 and performing an etch-back process on the dielectric material. The etch-back process for forming the first inter-cell dielectric layers 23 may be performed in the second direction D2.

The first inter-cell dielectric layers 23 may fill portions of the sacrificial isolation layer-level openings 22. The side surfaces of the first mold layers 12A and the side surfaces of the original body portions 13A may be covered by the first inter-cell dielectric layers 23 in the third direction D3. The first inter-cell dielectric layers 23 may expose the side surfaces of the narrow sheets 13P. The other portions of the sacrificial isolation layer-level openings 22, i.e., the non-gap-filled portions 22A, may expose the side surfaces of the narrow sheets 13P and extend to be disposed in the substrate 11. The first inter-cell dielectric layers 23 may be inter-cell vertical dielectric layers.

After the first inter-cell dielectric layers 23 are formed, a nano sheet all-open recess 24A that opens all of the narrow sheets 13P may be formed. The nano sheet all-open recess 24A may expose all of the narrow sheets 13P in the third direction D3. For example, the nano sheet all-open recess 24A extending in the third direction D3 may surround all surfaces of the narrow sheets 13P at the same horizontal level.

The nano sheet all-open recess 24A may refer to a combination of the inter-nano sheet recesses 21 and the non-gap-filled portions 22A of the sacrificial isolation layer-level openings 22. The nano sheet all-open recess 24A may include a plurality of surrounding recesses 24. The surrounding recesses 24 may expose all of the narrow sheets 13P in the third direction D3. For example, any of the surrounding recesses 24 extending in the third direction D3 may surround all surfaces of the narrow sheets 13P at the same horizontal level.

Each of the surrounding recesses 24 may include a plurality of first gaps 24G. The first gaps 24G may be included between the narrow sheets 13P in the third direction D3.

A horizontal arrangement of the narrow sheets 13P may be formed in the third direction D3. A vertical arrangement of the narrow sheets 13P may be formed in the first direction D1. The first gaps 24G may be referred to as horizontal gaps between the narrow sheets 13P in the horizontal arrangement.

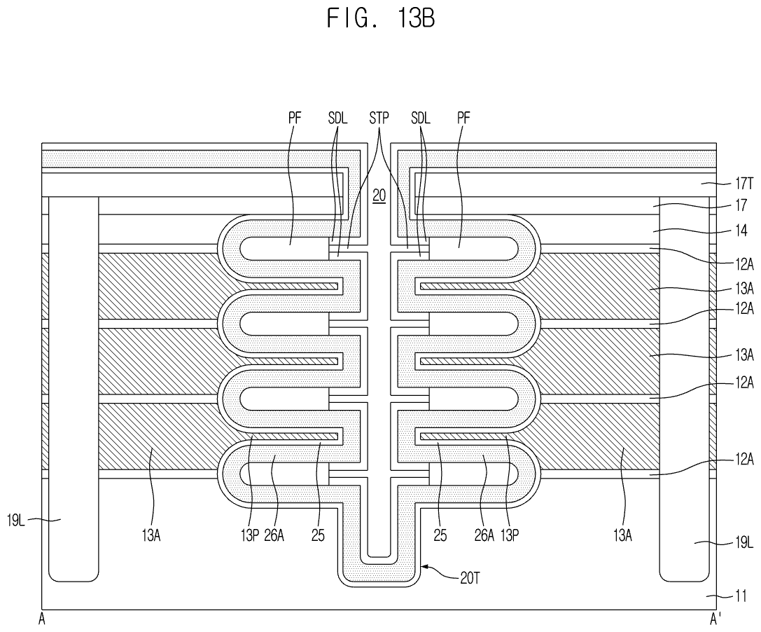

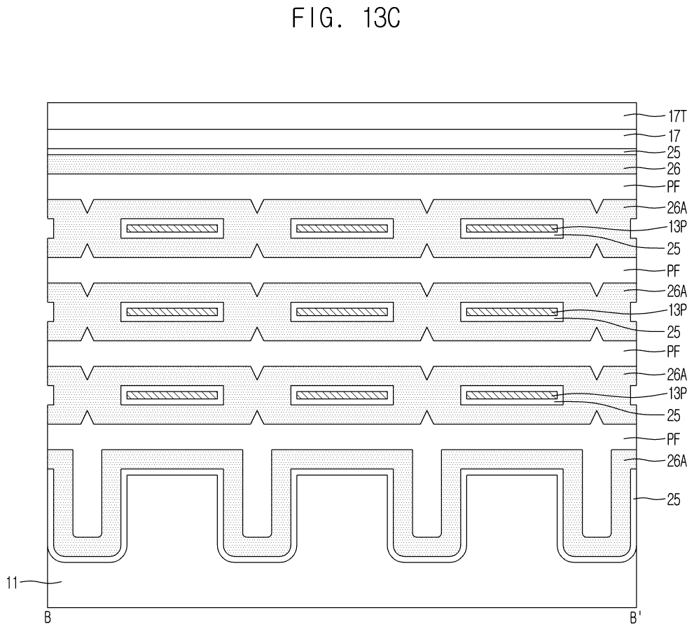

FIG. 12A is a plan view illustrating the structure at the narrow sheet level for describing a method for forming a first spacer layer 26A. FIG. 12B is a cross-sectional view illustrating the structure taken along line A-A′ illustrated in FIG. 12A. FIG. 12C is a cross-sectional view illustrating the structure taken along line B-B′ illustrated in FIG. 12A.

As illustrated in FIGS. 12A to 12C, a nano sheet dielectric layer 25 may be formed on exposed portions of the narrow sheets 13P. The nano sheet dielectric layer 25 may be referred to as a “gate dielectric layer”.

The nano sheet dielectric layer 25 may be formed by oxidizing the surfaces of the narrow sheets 13P. In some embodiments, the nano sheet dielectric layer 25 may be formed by a deposition process of silicon oxide and a surface oxidation process of the narrow sheets 13P. The nano sheet dielectric layer 25 may include silicon oxide, silicon nitride, metal oxide, metal oxide nitride, metal silicate, a high-k material, a ferroelectric material, an anti-ferroelectric material, or a combination thereof. The nano sheet dielectric layer 25 may include SiO₂, Si₃N₄, HfO₂, Al₂O₃, ZrO₂, AlON, HfON, HfSiO, HfSiON, or a combination thereof. The nano sheet dielectric layer 25 may be formed on all surfaces of the narrow sheets 13P.

The first spacer layer 26A may be formed on the nano sheet dielectric layer 25. The first spacer layer 26A may include silicon nitride. The first spacer layer 26A may surround and cover the narrow sheets 13P on the nano sheet dielectric layer 25. The first spacer layer 26A may be thicker than the nano sheet dielectric layer 25. The first spacer layer 26A may be in direct contact with the first inter-cell dielectric layers 23.

The nano sheet dielectric layer 25 and the first spacer layer 26A may also be formed on the surface of the substrate 11.

As described above, the first spacer layer 26A may be disposed between the narrow sheets 13P in the third direction D3. The first spacer layer 26A may define inner spaces 26B in upper and lower portions of the narrow sheets 13P.

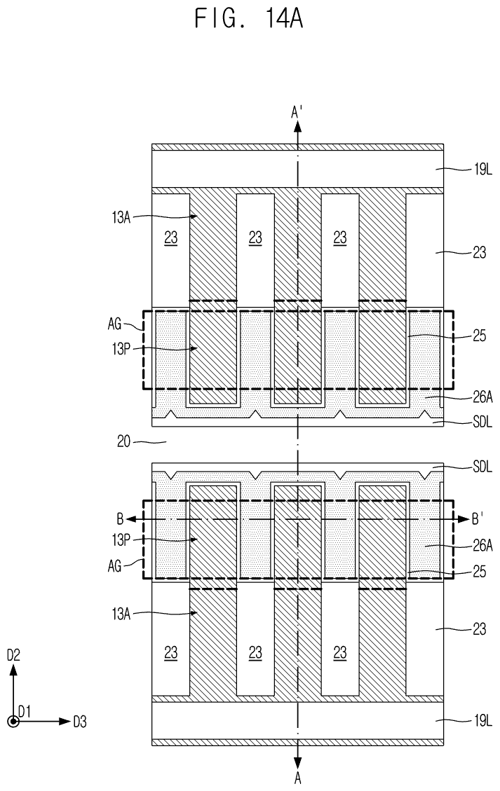

FIG. 13A is a plan view illustrating the structure at the narrow sheet level for describing a method for forming air gap target layers PF. FIG. 13B is a cross-sectional view illustrating the structure taken along line A-A′ illustrated in FIG. 13A. FIG. 13C is a cross-sectional view illustrating the structure taken along line B-B′ illustrated in FIG. 13A.

As illustrated in FIGS. 13A to 13C, the air gap target layers PF may be formed on the first spacer layer 26A. The air gap target layers PF may fill the inner spaces 26B of the first spacer layer 26A. The air gap target layers PF may each include a material having an etch selectivity with respect to the first spacer layer 26A. The air gap target layers PF may each include a material that is easy to be stripped including, for example, polysilicon or silicon oxide. For example, forming the air gap target layers PF may include forming polysilicon to fill the surrounding recesses 24 on the first spacer layer 26A and etching the polysilicon.

The air gap target layers PF may expose a portion of the first spacer layer 26A.

Strip barrier layers SDL may be formed on the exposed portions of the first spacer layer 26A exposed by the air gap target layers PF. The strip barrier layers SDL may be selectively deposited only on the exposed portions of the first spacer layer 26A. The strip barrier layers SDL may be discontinuous with one another. The strip barrier layers SDL may each include a dielectric material, for example, silicon carbon oxide (SiOC). When the first spacer layer 26A includes silicon nitride, the silicon carbon oxide may be selectively deposited on the silicon nitride among the silicon nitride and polysilicon. In some embodiments, the silicon carbon oxide may be selectively deposited on the silicon nitride among the silicon nitride and silicon oxide. Each of strip paths STP exposing side surfaces of the air gap target layers PF may be formed between the strip barrier layers SDL.

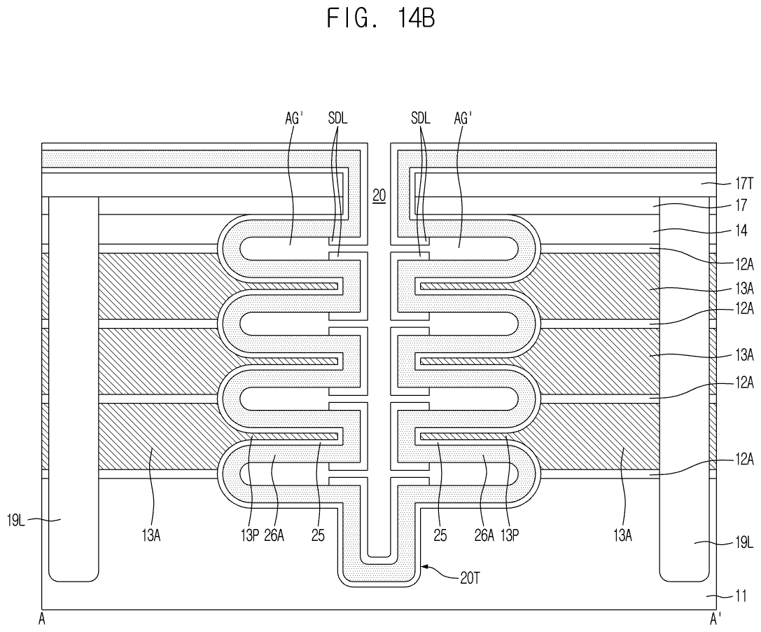

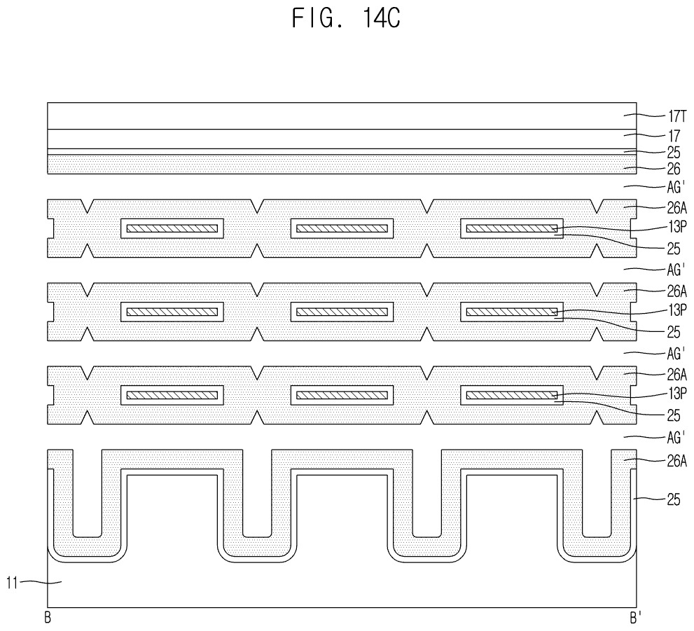

FIG. 14A is a plan view illustrating the structure at the narrow sheet level for describing a method for forming initial air gaps AG′. FIG. 14B is a cross-sectional view illustrating the structure taken along line A-A′ illustrated in FIG. 14A. FIG. 14C is a cross-sectional view illustrating the structure taken along line B-B′ illustrated in FIG. 14A.

As illustrated in FIGS. 14A to 14C, the air gap target layers PF may be stripped through the strip paths STP and form the initial air gaps AG′. When the air gap target layers PF are stripped, an attack of the first spacer layer 26A may be prevented by the strip barrier layers SDL.

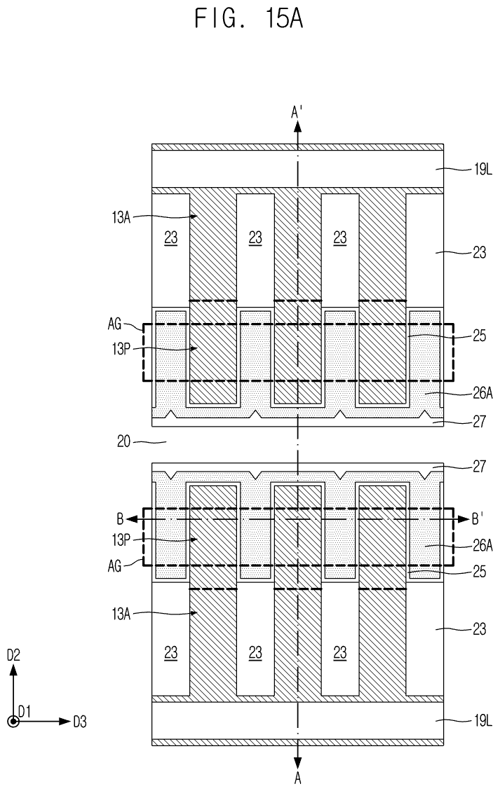

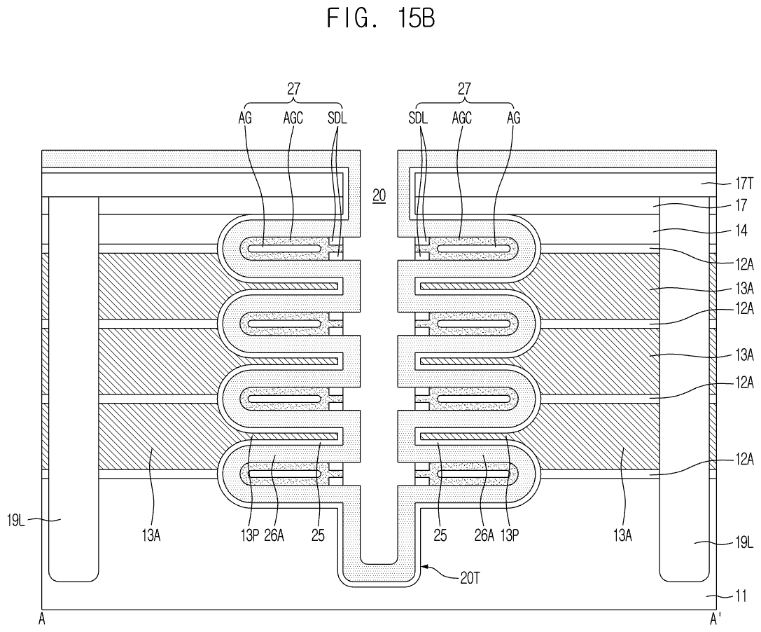

FIG. 15A is a plan view illustrating the structure at the narrow sheet level for describing a method for forming air gaps AG. FIG. 15B is a cross-sectional view illustrating the structure taken along line A-A′ illustrated in FIG. 15A. FIG. 15C is a cross-sectional view illustrating the structure taken along line B-B′ illustrated in FIG. 15A.

As illustrated in FIGS. 15A to 15C, air gap forming layers AGC may be formed to fill the initial air gaps AG′. The air gap forming layers AGC may each include a dielectric material such as, for example, silicon oxide.

Forming the air gap forming layers AGC may include depositing an air gap forming material filling the initial air gaps AG′ on the first spacer layer 26A and the strip barrier layers SDL and etching the air gap forming material to form the air gap forming layers AGC. The air gap forming layers AGC may each include an air gap AG. The air gap AG may be defined by a profile of each of the strip barrier layers SDL when the air gap forming material is deposited. That is, an entrance of the space where the air gap forming material is to be deposited may narrow by the strip barrier layers SDL, and accordingly, the air gap AG may be formed to be embedded in a film of each of the air gap forming layers AGC. The embedded air gap AG may be disposed inside the air gap forming layer AGC and may not contact the strip barrier layers SDL and the first spacer layer 26A.

The air gap forming layers AGC and the strip barrier layers SDL may constitute second inter-cell dielectric layers 27. The second inter-cell dielectric layers 27 may each be a silicon oxide-based material. The second inter-cell dielectric layers 27 disposed vertically adjacent to each other may be discontinuous with each other. The second inter-cell dielectric layers 27 may be first inter-cell horizontal dielectric layers.

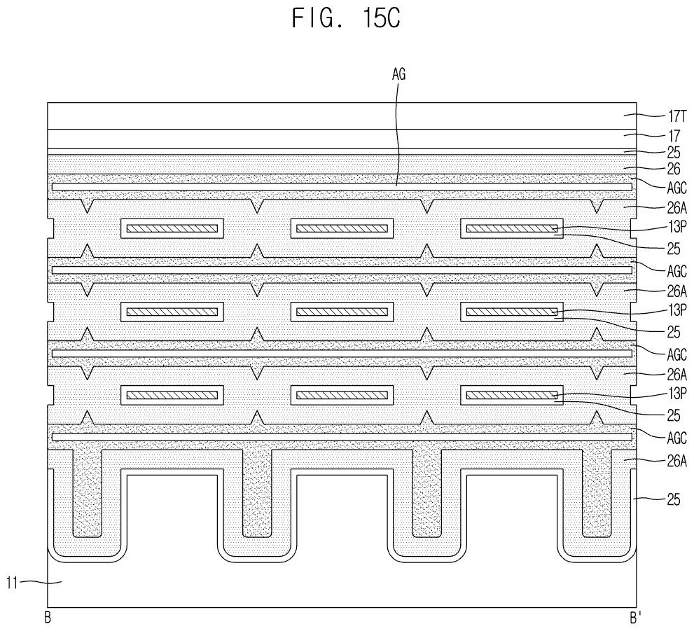

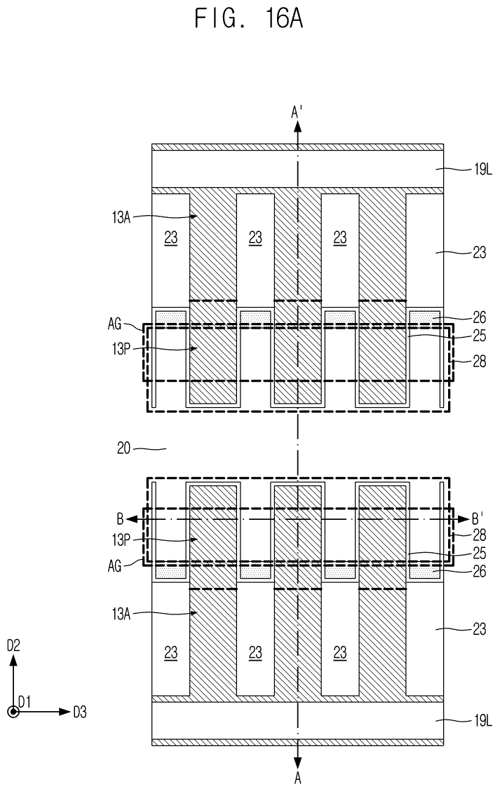

FIG. 16A is a plan view illustrating the structure at the narrow sheet level for describing a method for forming first spacers 26. FIG. 16B is a cross-sectional view illustrating the structure taken along line A-A′ illustrated in FIG. 16A. FIG. 16C is a cross-sectional view illustrating the structure taken along line B-B′ illustrated in FIG. 16A.

As illustrated in FIGS. 16A to 16C, the first spacer layers 26A may be selectively recessed through the first linear opening 20. The remaining first spacer layers may become the first spacers 26. The first spacers 26 may surround the narrow sheets 13P at the same horizontal level spaced apart from each other in the third direction D3.

As the first spacers 26 are formed, linear surrounding recesses 28 surrounding the narrow sheets 13P may be formed on the nano sheet dielectric layers 25. Each of the second inter-cell dielectric layers 27 may be disposed between the linear surrounding recesses 28. An upper-level dummy horizontal recess 28U may be formed on an uppermost second inter-cell dielectric layer 27, and a lower-level dummy horizontal recess 28L may be formed below a lowermost second inter-cell dielectric layer 27. The upper-level and lower-level dummy horizontal recesses 28U and 28L may each have a non-surrounding shape, i.e., a flat shape.

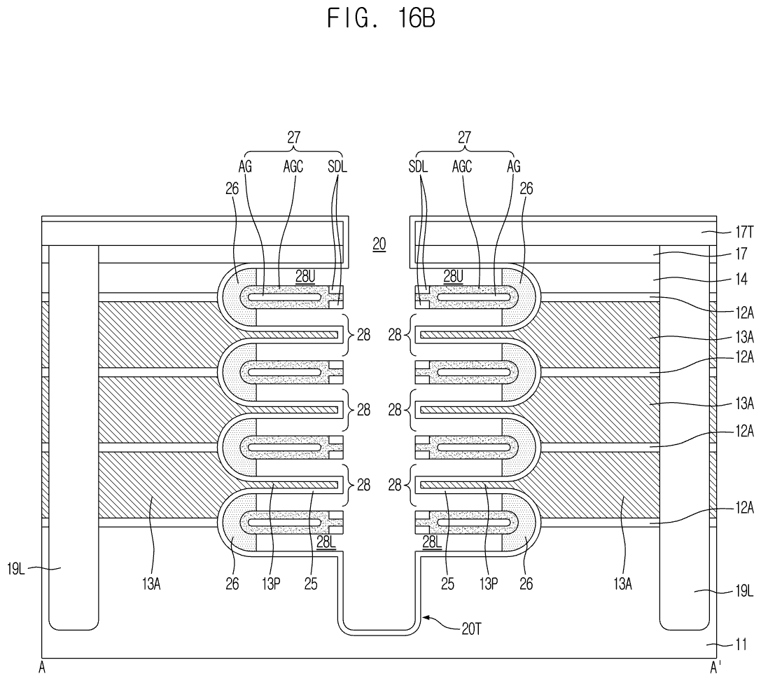

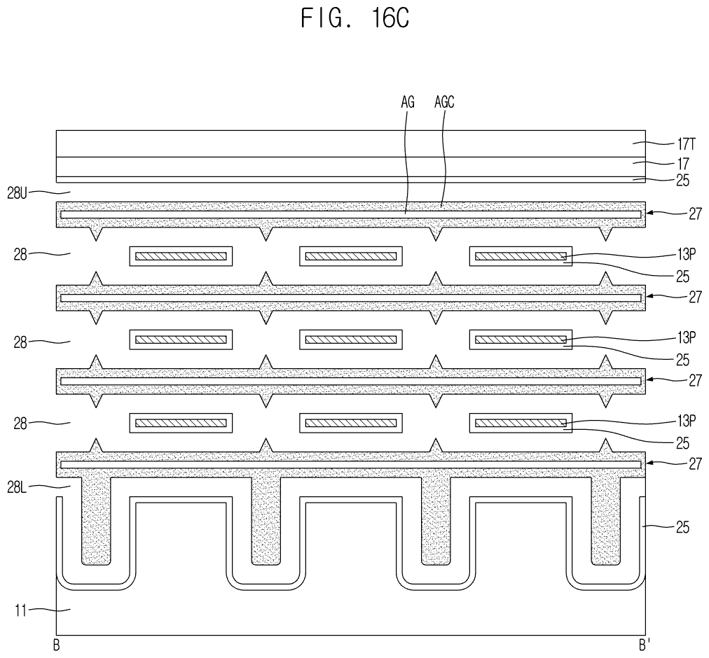

FIG. 17A is a plan view illustrating the structure at the narrow sheet level for describing a method for forming horizontal conductive lines 29. FIG. 17B is a cross-sectional view illustrating the structure taken along line A-A′ illustrated in FIG. 17A. FIG. 17C is a cross-sectional view illustrating the structure taken along line B-B′ illustrated in FIG. 17A.

As illustrated in FIGS. 17A to 17C, the horizontal conductive lines 29 filling the linear surrounding recesses 28 may be formed. The horizontal conductive lines 29 may horizontally extend in the third direction D3.

Forming the horizontal conductive lines 29 may include depositing a conductive material filling the linear surrounding recesses 28 on the nano sheet dielectric layer 25 and performing a horizontal etch-back process on the conductive material. Each of the horizontal conductive lines 29 may simultaneously surround the narrow sheets 13P at the same level. The horizontal conductive lines 29 may each include a metal-based material, a semiconductive material, or a combination thereof. The horizontal conductive lines 29 may each include molybdenum, molybdenum nitride, ruthenium, titanium nitride, tungsten, polysilicon, or a combination thereof. For example, the horizontal conductive lines 29 may each include a TiN/W stack in which titanium nitride and tungsten are sequentially stacked. The horizontal conductive lines 29 may each include an N-type work function material or a P-type work function material. The N-type work function material may have a low work function of approximately 4.5 eV or lower, and the P-type work function material may have a high work function of approximately 4.5 eV or higher. Each of the second inter-cell dielectric layers 27 may be disposed between a plurality of horizontal conductive lines 29 in the first direction D1. The horizontal conductive lines 29 surrounding the narrow sheets 13P may be referred to as “gate-all-around (GAA) electrodes”. The narrow sheets 13P may be referred to as “nano sheet channels”, “nano wires” or “nano wire channels”.

A lower-level dummy horizontal electrode 29L may be formed on the surface of the substrate 11, and an upper-level dummy horizontal electrode 29U may be formed over an uppermost horizontal conductive line 29. The dummy horizontal electrodes 29L and 29U may each have a non-surrounding shape.

The horizontal conductive lines 29 and the first spacers 26 may extend in the third direction D3. The horizontal conductive lines 29 and the first spacers 26 may surround the narrow sheets 13P of the preliminary nano sheets disposed at the same horizontal level in the third direction D3.

Each of the second inter-cell dielectric layers 27 may be disposed between the horizontal conductive lines 29 disposed vertically adjacent to each other. Each of the second inter-cell dielectric layers 27 may include the strip barrier layer SDL and the air gap forming layer AGC, and the air gap AG may be embedded in the air gap forming layer AGC. The strip barrier layer SDL may include silicon carbon oxide (SiOC), and the air gap forming layer AGC may include silicon oxide. The air gap forming layer AGC may be silicon oxide in which the air gap AG is embedded. Parasitic capacitance between the horizontal conductive lines 29 stacked in the first direction D1 may be reduced by the air gap AG, and thus an RC delay (resistance-capacitance delay) may also be reduced. When the RC delay is reduced, a cell mat size may increase, and accordingly, a cell density may also increase.

As described above, the method for fabricating the semiconductor device may include forming the nano sheet target layers 13 vertically stacked spaced apart from each other in the first direction D1 over the substrate 11, trimming the first portions of the nano sheet target layers 13 and forming the narrow sheets 13P that extend in the second direction D2 intersecting the first direction D1, forming the initial air gaps AG′ between the narrow sheets 13P stacked in the first direction D1, forming the air gap forming layers AGC that fill the initial air gaps AG′ and in which the air gaps AG are embedded, forming the surrounding recesses 28 that expose the narrow sheets 13P in the third direction D3 intersecting the first and second directions D1 and D2 between the air gap forming layers AGC, and forming the horizontal conductive lines 29 that fill the surrounding recesses 33 in the third direction D3 and are disposed between the air gap forming layers AGC.

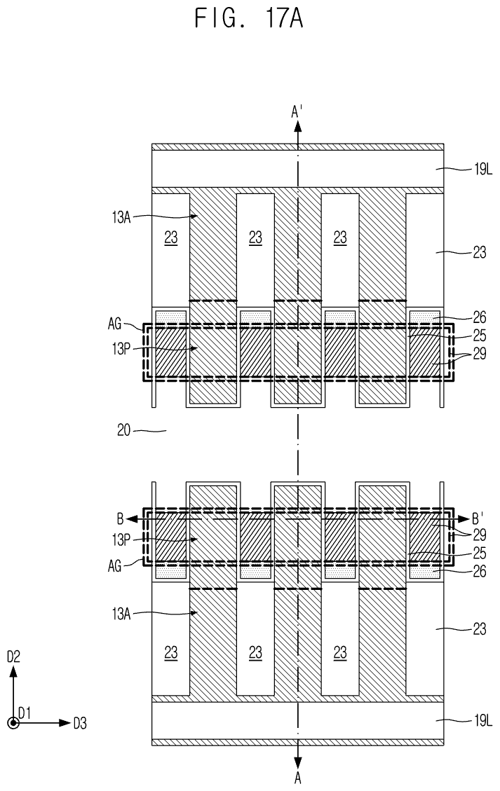

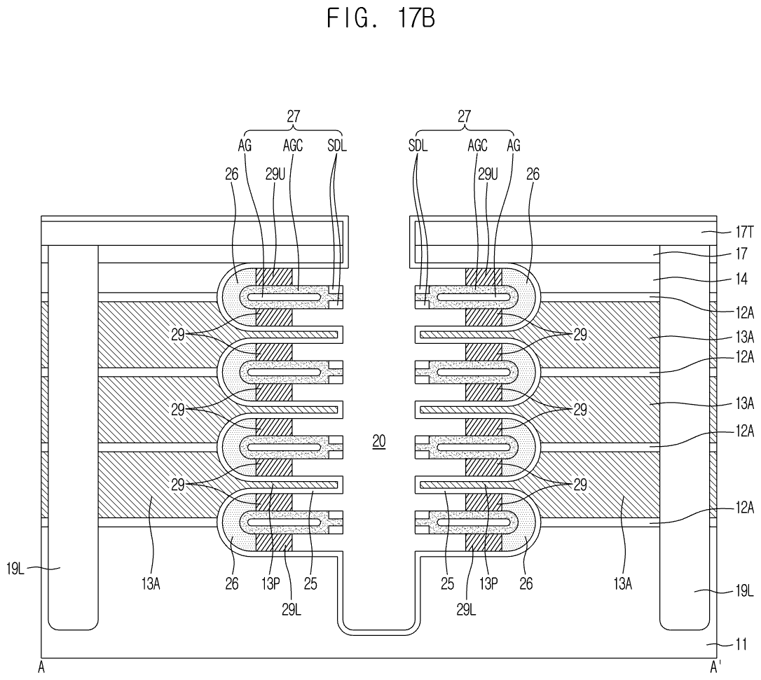

FIG. 18A is a plan view illustrating the structure at the narrow sheet level for describing a method for forming second spacers 30. FIG. 18B is a cross-sectional view illustrating the structure taken along line A-A′ illustrated in FIG. 18A.

As illustrated in FIGS. 18A and 18B, each of the second spacers 30 may be formed on one side of the horizontal conductive lines 29. The second spacer 30 may include silicon oxide, silicon nitride, silicon carbon oxide, an embedded air gap, or a combination thereof. Deposition and etch-back processes of a spacer material may be performed to form the second spacer 30. The second spacer 30 may include a stack of a silicon oxide liner 31A and a silicon nitride liner 31B. A portion of the silicon nitride liner 31B may protrude into the first linear opening 20. The second spacer 30 may surround the narrow sheets 13P at the same horizontal level disposed in the third direction D3. The second spacer 30 may extend in the third direction D3.

Subsequently, deposition and etch-back processes of a first bottom protective layer 32 may be performed. An upper surface of the first bottom protective layer 32 may be disposed at a level lower than a lowermost horizontal conductive line 29. The first bottom protective layer 32 may include a dielectric material including, for example, silicon oxide, silicon nitride, silicon carbon oxide, or a combination thereof.

After the first bottom protective layer 32 is formed, a portion of the nano sheet dielectric layer 25 may be cut to expose each side of the narrow sheets 13P.

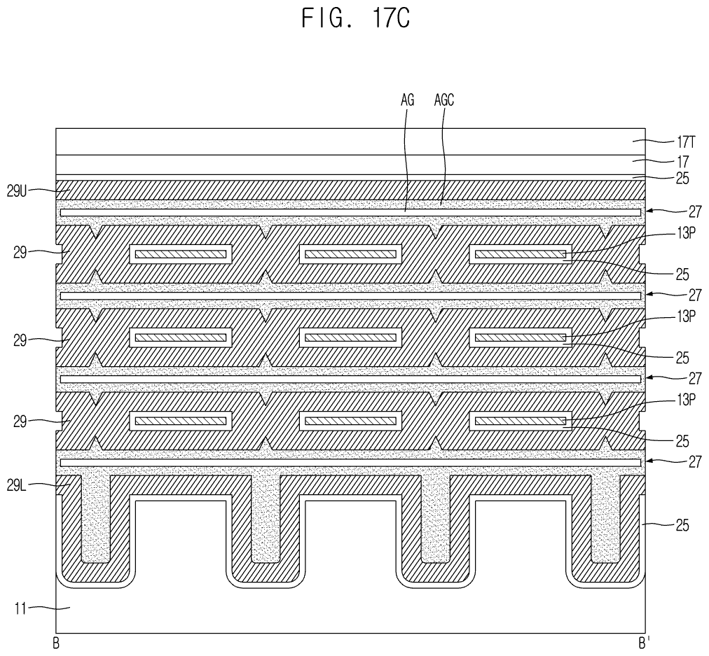

FIG. 19A is a plan view illustrating the structure at the narrow sheet level for describing a method for recessing the narrow sheets 13P. FIG. 19B is a cross-sectional view illustrating the structure taken along line A-A′ illustrated in FIG. 19A.

As illustrated in FIGS. 19A and 19B, the narrow sheets 13P may be horizontally recessed. Nano sheet level recesses 33 may be formed by the recessing of the narrow sheets 13P. Each of the nano sheet level recesses 33 may be a side-recess disposed in the second spacer 30.

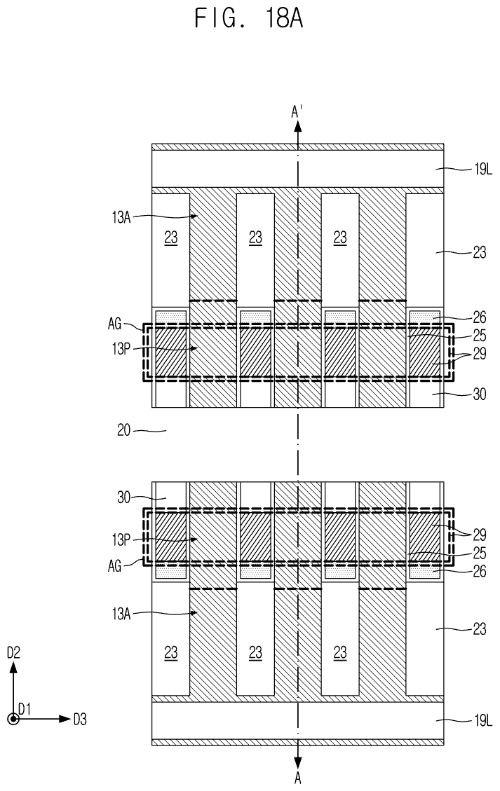

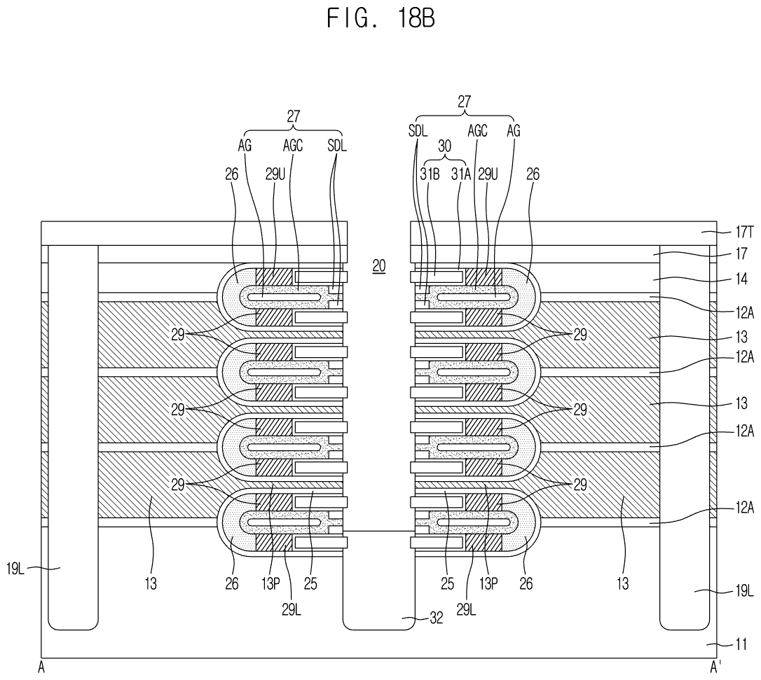

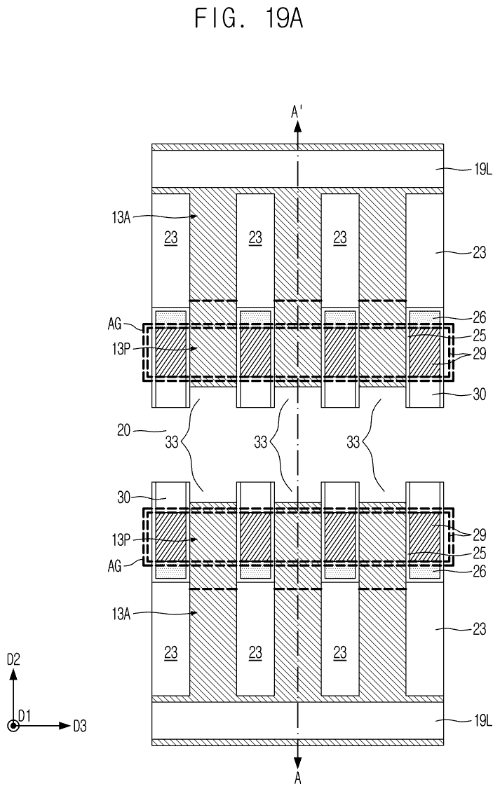

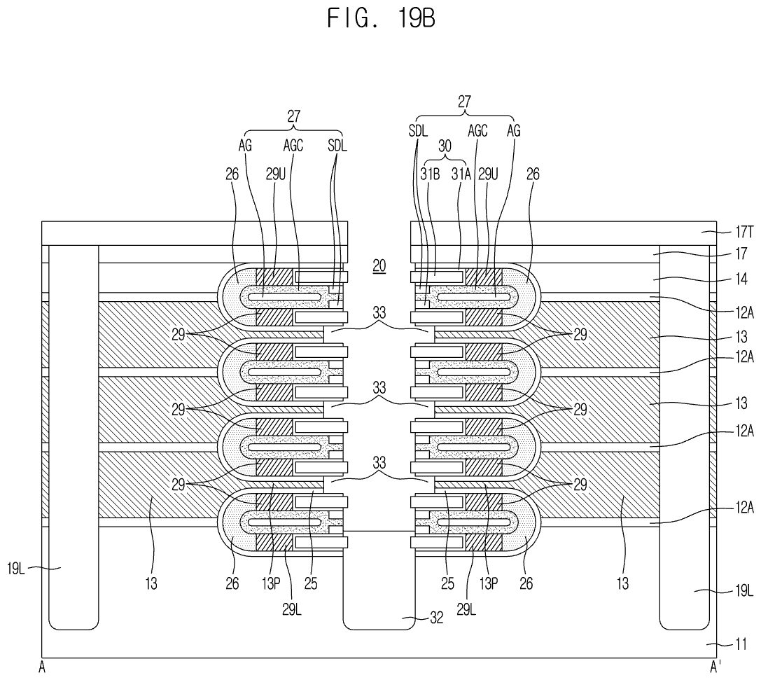

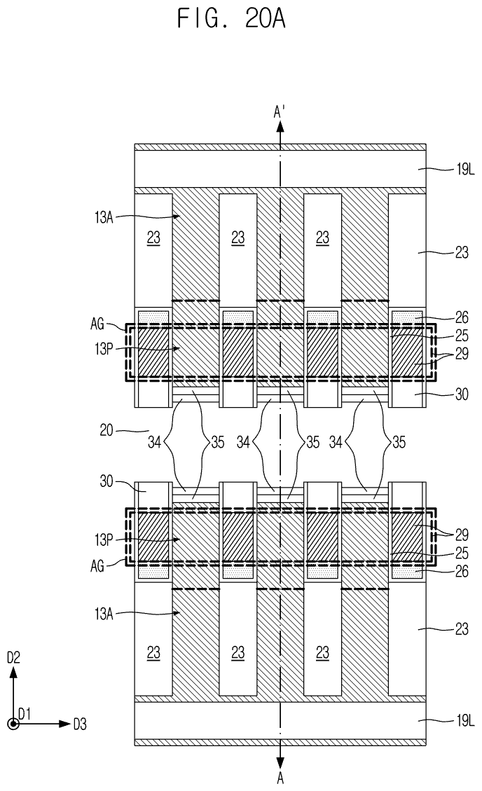

FIG. 20A is a plan view illustrating the structure at the narrow sheet level for describing a method for forming first contact nodes 34. FIG. 20B is a cross-sectional view illustrating the structure taken along line A-A′ illustrated in FIG. 20A.

As illustrated in FIGS. 20A and 20B, the first contact nodes 34 may be formed to fill the nano sheet level recesses 33. Forming the first contact nodes 34 may include depositing a conductive material filling the nano sheet level recesses 33 and performing an etch-back process on the conductive material. The first contact nodes 34 may each include a semiconductive material including, for example, doped polysilicon, and the doped polysilicon may include N-type dopants. The first contact nodes 34 may fill the nano sheet level recesses 33 disposed in the second spacer 30. Another method for forming the first contact nodes 34 may also include applying a selective epitaxial growth (SEG) of a doped semiconductive material.

Each of first doped regions 35 may be formed in one side of each of the narrow sheets 13P. A heat treatment process may be performed to form the first doped regions 35, and thus the dopants may be diffused from the first contact nodes 34.

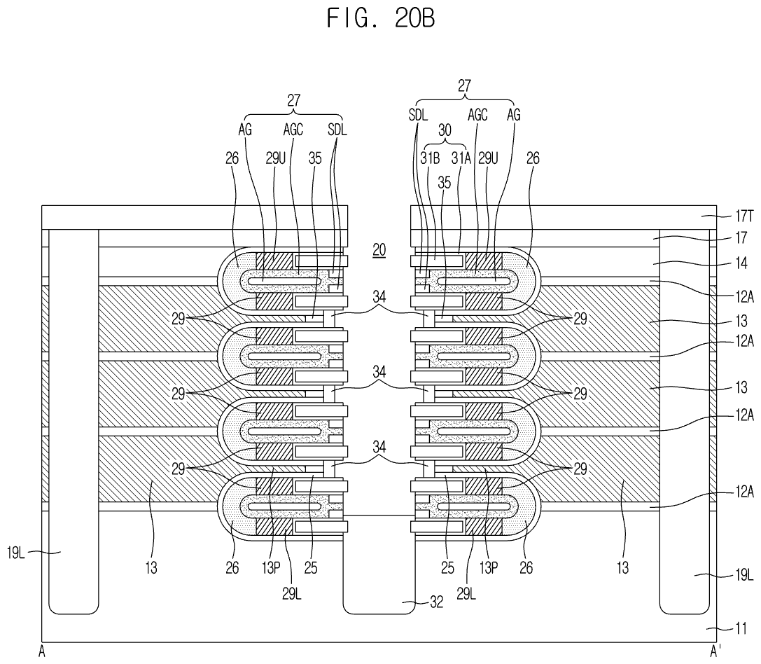

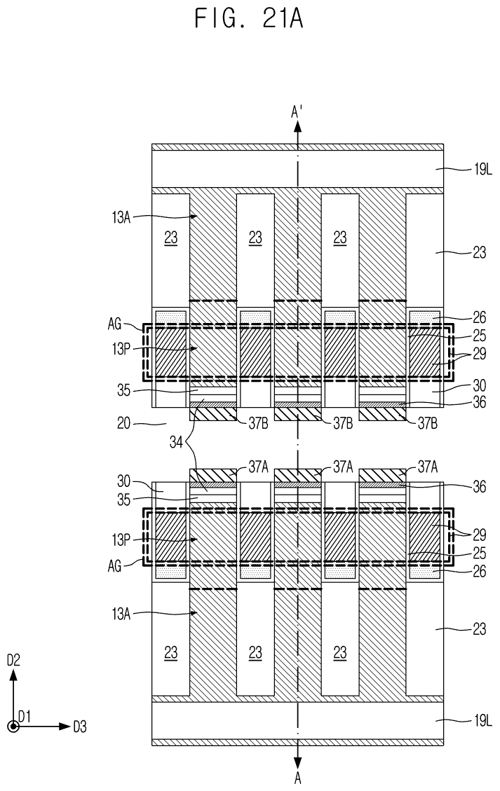

FIG. 21A is a plan view illustrating the structure at the narrow sheet level for describing a method for forming vertical conductive lines 37A and 37B. FIG. 21B is a cross-sectional view illustrating the structure taken along line A-A′ illustrated in FIG. 21A.

As illustrated in FIGS. 21A and 21B, ohmic contact layers 36 may be formed on the first contact nodes 34. The ohmic contact layers 36 may each include metal silicide.

The vertical conductive lines 37A and 37B may be formed on the ohmic contact layers 36. The vertical conductive lines 37A and 37B may be coupled in common to the ohmic contact layers 36. Accordingly, the vertical conductive lines 37A and 37B may be coupled in common to the narrow sheets 13P disposed in the first direction D1. The vertical conductive lines 37A and 37B may each include a metal-based material. The vertical conductive lines 37A and 37B may each include titanium nitride, tungsten, or a combination thereof.

The deposition and etch processes may be performed on a vertical conductive line material to form the vertical conductive lines 37A and 37B.

Bottom portions of the vertical conductive lines 37A and 37B may be merged with each other (refer to reference numeral “38”). The vertical conductive lines 37A and 37B may be disposed in the first linear opening 20. The vertical conductive lines 37A and 37B may vertically extend in the first direction D1. The bottom portions of the vertical conductive lines 37A and 37B may be merged with each other. The vertical conductive lines 37A and 37B may be coupled in common to the ohmic contact layers 36. Accordingly, the vertical conductive lines 37A and 37B may be coupled in common to the narrow sheets 13P disposed in the first direction D1.

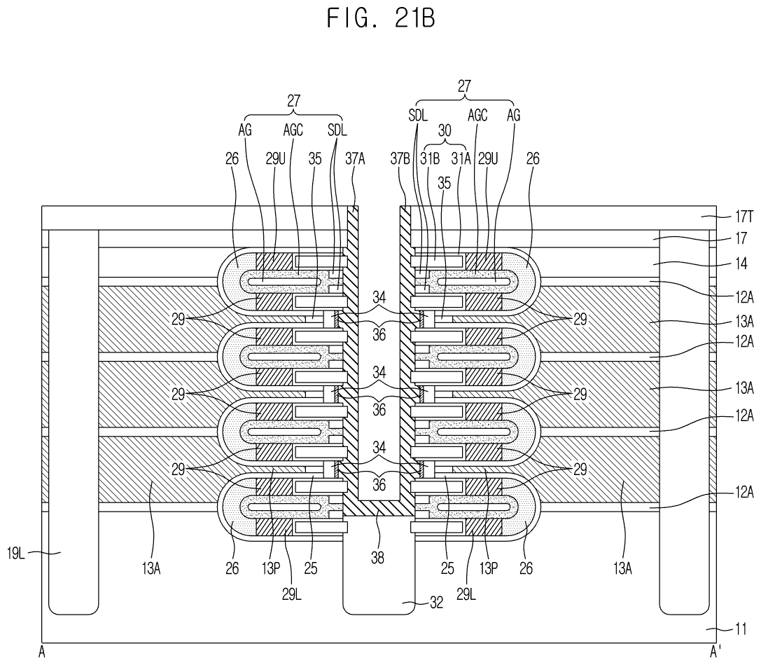

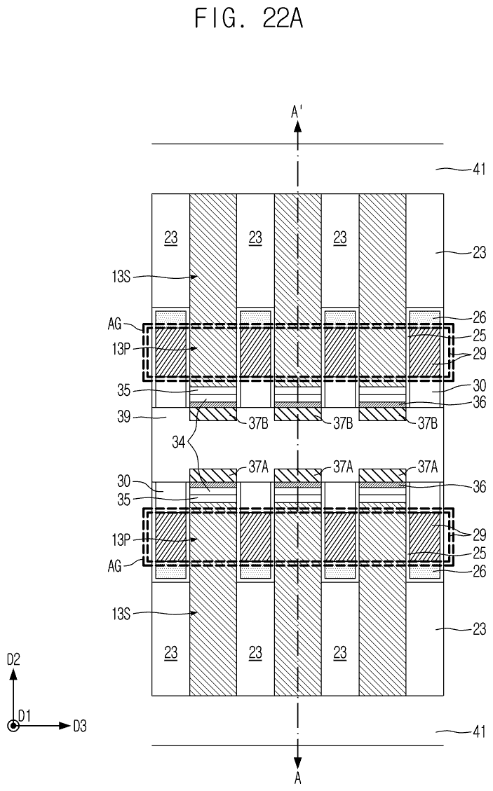

FIG. 22A is a plan view illustrating the structure at a nano sheet level for describing a method for forming second linear openings 41. FIG. 22B is a cross-sectional view illustrating the structure taken along line A-A′ illustrated in FIG. 22A.

As illustrated in FIGS. 22A and 22B, a vertical isolation layer 39 may be formed to fill the first linear opening 20 on the vertical conductive lines 37A and 37B. The vertical isolation layer 39 may vertically extend in the first direction D1 and horizontally extend in the third direction D3. The vertical conductive lines 37A and 37B disposed adjacent to each other in the third direction D3 may be isolated by the vertical isolation layer 39. The vertical isolation layer 39 may include a dielectric material. The vertical isolation layer 39 may include silicon oxide, silicon nitride, an air gap, or a combination thereof.

Subsequently, the second linear sacrificial layer 19L may be removed using the fourth hard mask layer 40 as a barrier. Accordingly, the second linear openings 41 may be formed.

After the second linear openings 41 are formed, the first mold layers 12A may be selectively recessed through the second linear openings 41. The difference in etch selectivity between the first mold layers 12A and the original body portions 13A may be used to selectively recess the first mold layers 12A. The first mold layers 12A may be removed using a wet etch process or a dry etch process. For example, when the first mold layers 12A include silicon germanium layers and the original body portions 13A include monocrystalline silicon layers, the silicon germanium layers may be etched using an etchant or etch gas having a selectivity with respect to the monocrystalline silicon layers.

Subsequently, the original body portions 13A may be recessed. The wet etch process or the dry etch process may be used to recess the original body portions 13A. Vertical thicknesses of the original body portions 13A may be reduced, as indicated by reference numeral “13S”. Hereinafter, the original body portions having the reduced vertical thicknesses are referred to as “recessed body portions 13S”.

Each of inter-body recesses 42 may be formed between the recessed body portions 13S that are vertically disposed.

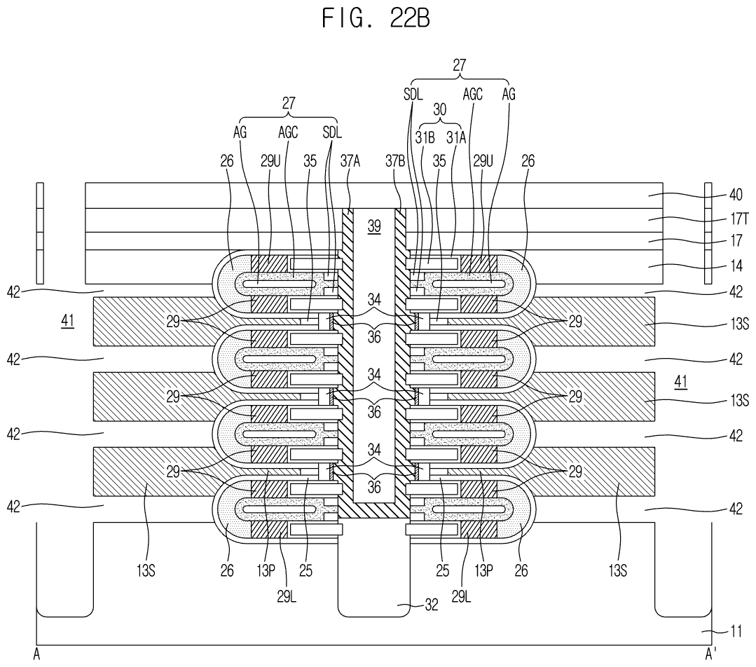

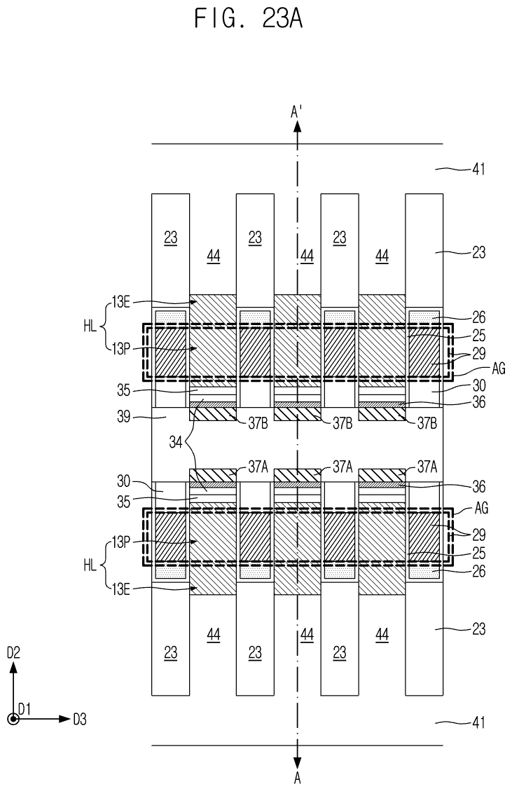

FIG. 23A is a plan view illustrating the structure at the narrow sheet level for describing a method for forming nano sheets HL. FIG. 23B is a cross-sectional view illustrating the structure taken along line A-A′ illustrated in FIG. 23A.

As illustrated in FIGS. 23A and 23B, third inter-cell dielectric layers 43 may be formed to fill the inter-body recesses 42. The third inter-cell dielectric layers 43 may each include silicon oxide. The third inter-cell dielectric layers 43 may be second inter-cell horizontal dielectric layers.

After the third inter-cell dielectric layers 43 are formed, a second bottom protective layer 44T may be formed on a bottom portion of the second linear opening 41. The second bottom protective layer 44T may include a material having an etch selectivity with respect to the substrate 11. The second bottom protective layer 44T may include a dielectric material. The second bottom protective layer 44T may include silicon oxide, silicon nitride, silicon carbon oxide, or a combination thereof.

After the second bottom protective layer 44T is formed, storage openings 44 may be formed by horizontal recessing of the recessed body portions 13S. The storage openings 44 may be referred to as “capacitor openings”. The nano sheets HL may be formed by the horizontal recessing of the recessed body portions 13S. Each of the nano sheets HL may include a narrow sheet 13P and a wide sheet 13E. The wide sheet 13E of the nano sheet HL may refer to the recessed body portion 13S remaining after the recessing. An average vertical height of the wide sheet 13E of the nano sheet HL in the first direction D1 may be greater than an average vertical height of the narrow sheet 13P. A thickness of the wide sheet 13E of the nano sheet HL may gradually increase in the second direction D2. A horizontal length of the wide sheet 13E in the second direction D2 may be shorter than a horizontal length of the narrow sheet 13P. The wide sheet 13E of the nano sheet HL may have a fan-like shape. The wide sheet 13E may be referred to as a “fan-shaped sheet”, and the narrow sheet 13P may be referred to as a “flat plate-shaped sheet”.

The recessing process of the recessed body portions 13S for forming the wide sheets HL and the storage openings 44 may include an isotropic etch process or an anisotropic etch process. One side of each of the wide sheets 13E, i.e., the side exposed by each of the storage openings 44, may have a flat shape (refer to reference symbol “RF”). The one side of the wide sheet 13E may have various shapes. For example, the one side of the wide sheet 13E may have a rounded concave shape, a rounded convex shape, an angled concave shape, or an angled convex shape.

The second bottom protective layer 44T and a lowermost second inter-cell dielectric layer 43 may prevent loss of the substrate 11 during the recessing process of the recessed body portions 13S.

Each of the nano sheets HL may include a first edge and a second edge. The first edge may refer to a portion coupled to the vertical conductive lines 37A and 37B, and the second edge may refer to a portion exposed by each of the storage openings 44.

Each of the storage openings 44 may be disposed between the third inter-cell dielectric layers 43.

In some embodiments, the horizontal recessing of the recessed body portions 13S for forming the wide sheets 13E may stop at a boundary area between the narrow sheet 13P and the wide sheet 13E.

FIG. 24A is a plan view illustrating the structure at the nano sheet level for describing a method for forming second contact nodes 45 and first electrodes 48. FIG. 24B is a cross-sectional view illustrating the structure taken along line A-A′ illustrated in FIG. 24A.

As illustrated in FIGS. 24A and 24B, a pre-cleaning process may be performed on one side of each of the nano sheets HL, that is, the surface of each of the wide sheets 13E.

Subsequently, the second contact nodes 45 may be formed on the second edges of the nano sheets HL, that is, the wide sheets 13E. Forming the second contact nodes 45 may include deposition and etch processes of doped polysilicon. In some embodiments, forming the second contact nodes 45 may include a selective epitaxial growth (SEG). For example, a semiconductive material may be grown from the side surfaces of the wide sheets 13E through the selective epitaxial growth (SEG). The second contact nodes 45 may each include SEG Si. Since the wide sheets 13E each include monocrystalline silicon, a silicon layer may be epitaxially grown along crystal surfaces of the side surfaces of the wide sheets 13E. The second contact nodes 45 may each include a dopant. Accordingly, the second contact nodes 45 may each be a doped epitaxial layer. The second contact nodes 45 may each include an N-type dopant as the dopant. The N-type dopant may include phosphorus, arsenic, antimony, or a combination thereof. The second contact nodes 45 may include a phosphorus-doped silicon epitaxial layer formed by the selective epitaxial growth (SEG), i.e., a doped SEG SiP. In some embodiments, the first contact nodes 34 may also be formed by the selective epitaxial growth (SEG).

Since the second contact nodes 45 are formed using the selective epitaxial growth (SEG), void-free or seam-free second contact nodes 45 may be formed. Since the second contact nodes 45 are formed using the selective epitaxial growth (SEG), a process for forming the second contact nodes 45 may be simplified.

Each of the second contact nodes 45 may be disposed between the third inter-cell dielectric layers 43 that are vertically stacked.

In some embodiments, the side surfaces of the second contact nodes 45 may each have a rounded concave shape, a rounded convex shape, an angled concave shape, or an angled convex shape.

Second doped regions 46 may be formed in the wide sheets 13E of the nano sheets HL. A heat treatment process may be performed to form the second doped regions 46, and thus, dopants may be diffused from the second contact nodes 45.

Each of the nano sheets HL may include the first doped region 34, the second doped region 46, and a channel 47. The first doped region 34 and the channel 47 may be formed in the narrow sheet 13P, and the second doped region 46 may be formed in the wide sheet 13E. A portion of each of the second doped regions 46 may extend into the narrow sheet 13P. One side of each of the second doped regions 46 of the nano sheets HL may be coupled to the channel 47, and the other side of each of the second doped regions 46 of the nano sheets HL may be coupled to the second contact node 45.

In some embodiments, an ohmic contact layer including metal silicide may be further formed after the second contact nodes 45 are formed.

Subsequently, the first electrodes 48 of a data storage element CAP may be formed on the second contact nodes 45. The first electrodes 48 may each have a horizontally-oriented cylindrical shape. The first electrodes 48 may be disposed in the storage openings 44, respectively. The first electrodes 48 disposed adjacent to each other in the second direction D2 may be spaced apart from each other by the second linear openings 41. The first electrodes 48 disposed adjacent to each other in the third direction D3 may be spaced apart from each other by the first inter-cell dielectric layers 23. Forming the first electrodes 48 may include depositing a metal material, gap-filling a sacrificial material, and isolating the metal material in a vertical/horizontal direction. The sacrificial material may include oxide or polysilicon.

Each of the first electrodes 48 may include an inner space and a plurality of outer surfaces, and the inner space of the first electrode 48 may include a plurality of inner surfaces. The outer surfaces of the first electrode 48 may include a vertical outer surface and a plurality of horizontal outer surfaces. The vertical outer surface of the first electrode 48 may vertically extend in the first direction D1, and the horizontal outer surfaces of the first electrode 48 may horizontally extend in the second direction D2 or the third direction D3. The inner space of the first electrode 48 may be a three-dimensional space.

Among the outer surfaces of the first electrode 48, the vertical outer surface may be electrically coupled to the nano sheet HL and the second contact node 45.

The first electrode 48 may include metal, noble metal, metal nitride, conductive metal oxide, conductive noble metal oxide, metal carbide, metal silicide, or a combination thereof. For example, the first electrode 48 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, or a combination thereof.

FIG. 25A is a plan view illustrating the structure at the nano sheet level for describing a method for recessing the first and third inter-cell dielectric layers 23 and 43. FIG. 25B is a cross-sectional view illustrating the structure taken along line A-A′ illustrated in FIG. 25A.

As illustrated in FIGS. 25A and 25B, portions of the first and third inter-cell dielectric layers 23 and 43 may be horizontally recessed (refer to reference numeral “43R”). Accordingly, the outer walls of the first electrodes 48 may be partially exposed. The first electrodes 48 may each have a semi-cylindrical shape. The semi-cylindrical shape of the first electrode 48 may include cylindrical inner surfaces and semi-cylindrical outer surfaces.

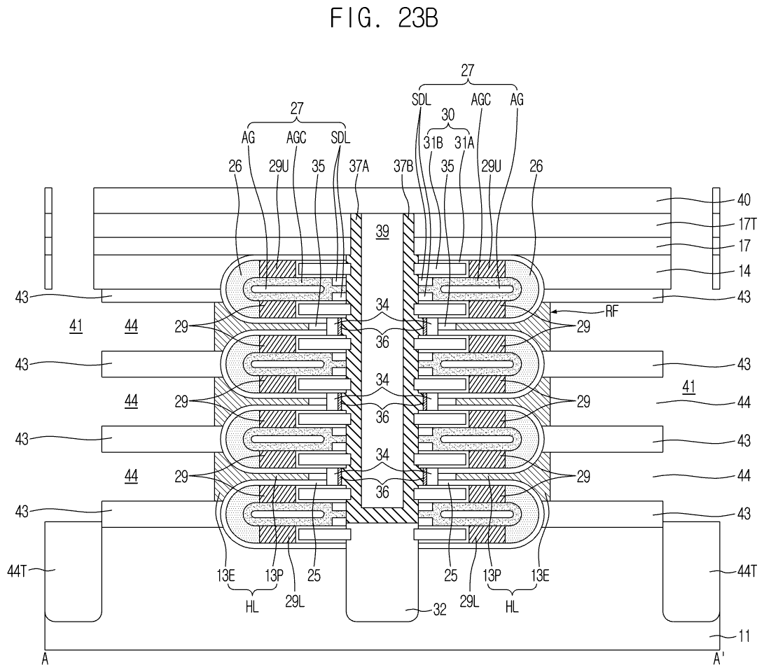

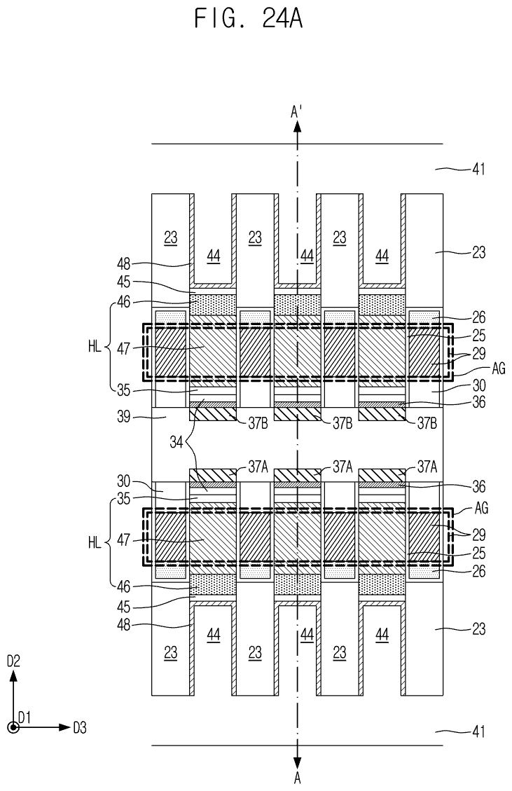

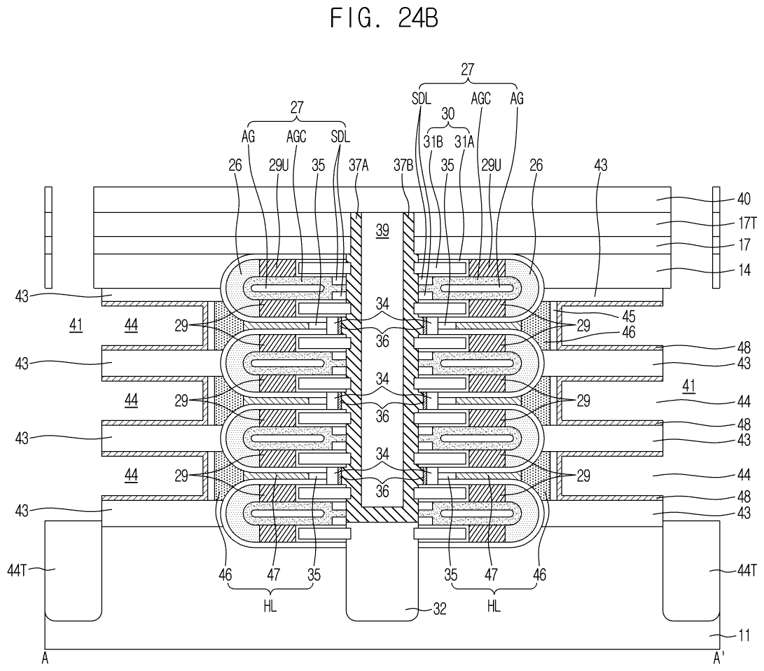

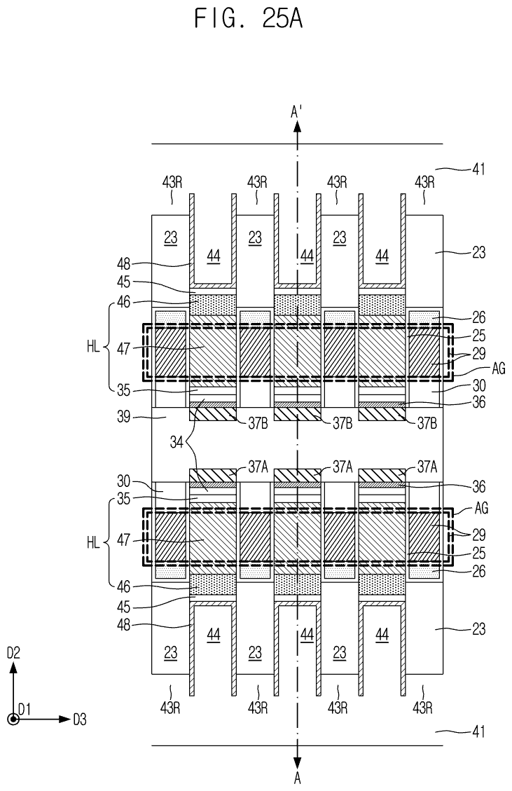

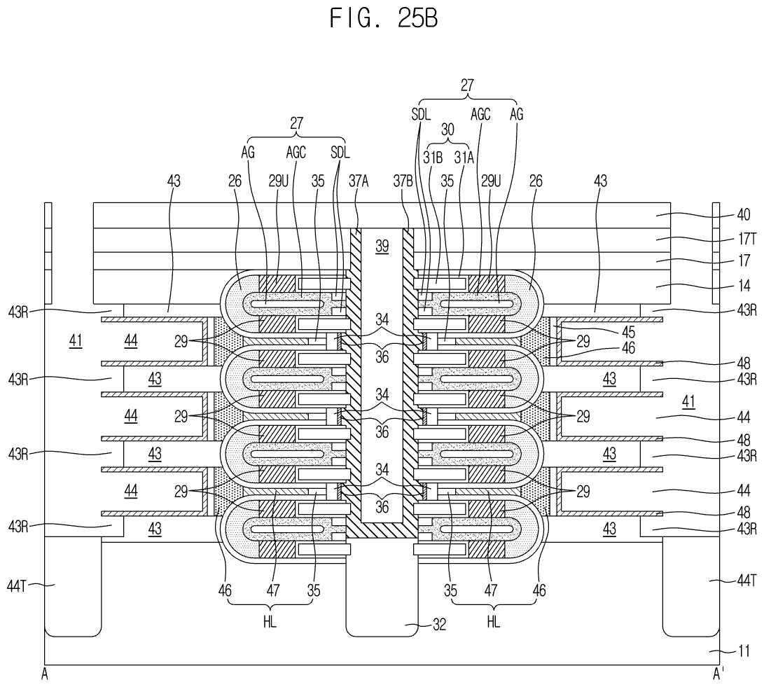

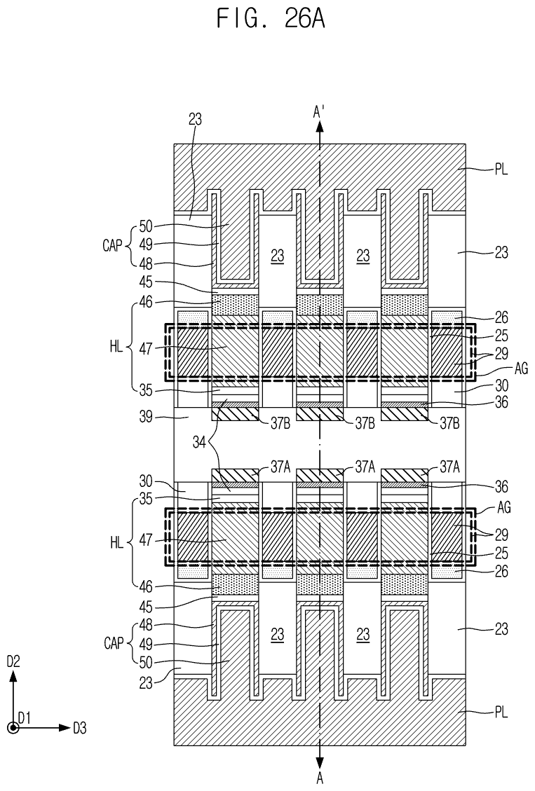

FIG. 26A is a plan view illustrating the structure at the nano sheet level for describing a method for forming second electrodes 50 of the data storage element CAP. FIG. 26B is a cross-sectional view illustrating the structure taken along line A-A′ illustrated in FIG. 26A.

As illustrated in FIGS. 26A and 26B, a dielectric layer 49 and the second electrodes 50 may be sequentially formed on the first electrodes 48. The first electrode 48, the dielectric layer 49 and the second electrode 50 may be the data storage element CAP. The second electrodes 50 of the data storage elements CAP may be merged with one another and form a common plate PL.

The dielectric layer 49 and the second electrode 50 may be disposed on the cylindrical inner surfaces of the first electrode 48. A portion of the dielectric layer 49 and a portion of the second electrode 50 may extend to be disposed on the semi-cylindrical outer surfaces of the first electrode 48. The second electrode 50 may vertically extend in the first direction D1.

The dielectric layer 49 may be referred to as a “capacitor dielectric layer” or a “memory layer”. The dielectric layer 49 may include silicon oxide, silicon nitride, a high-k material, a ferroelectric material, an antiferroelectric material, a perovskite material, or a combination thereof. The dielectric layer 49 may include a high-k material such as hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). The dielectric layer 49 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH(HfO₂/ZrO₂/Al₂O₃/ZrO₂/HfO₂) stack, a ZHZAZHZ(ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA(Al₂O₃/HfO₂/ZrO₂/Al₂O₃/ZrO₂/HfO₂/Al₂O₃) stack.

The second electrode 50 may include metal, noble metal, metal nitride, conductive metal oxide, conductive noble metal oxide, metal carbide, metal silicide, or a combination thereof. For example, the second electrode 50 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TiN/W) stack, or a combination thereof. The second electrode 50 may also include a combination of a metal-based material and a silicon-based material. For example, the second electrode 50 may have a structure in which titanium nitride, tungsten and polysilicon are sequentially stacked.

In some embodiments, an interface control layer may be further formed between the first electrode 48 and the dielectric layer 49 to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 50 and the dielectric layer 49.

As described above, the method for fabricating the semiconductor device may include forming the nano sheet target layers 13 that are vertically stacked spaced apart from each other over the substrate 11, forming the flat plate-shaped sheets 13P by trimming first portions of the nano sheet target layers 13, forming the horizontal conductive lines 29 extending while surrounding the flat plate-shaped sheets 13P disposed at the same horizontal level, forming the first contact nodes 34 coupled to the flat plate-shaped sheets 13P, forming the vertical conductive lines 37A and 37B coupled to the first contact nodes 34, horizontally recessing second portions of the nano sheet target layers 13 to form the fan-shaped sheets 13E, selectively growing the second contact nodes 45 on side surfaces of the fan-shaped sheets 13E, and forming the data storage element CAP coupled to the second contact nodes 45. Before forming the horizontal conductive lines 29, the method for fabricating the semiconductor device may include forming the first spacer layer 26A defining the inner spaces 26B in the upper and lower portions of the flat plate-shaped sheets 13P, forming the air gap target layers PF filling the inner spaces 26B, forming the strip barrier layers SDL and the strip paths STP between the strip barrier layers SDL at the entrance of the inner spaces 26B, forming the initial air gaps AG′ by removing the air gap target layers PF through the strip paths STP, forming the air gap forming layers AGC in which the air gaps AG are embedded while filling the initial air gaps AG′, and horizontally recessing the first spacer layer 26A to form the first spacers 26 covering the side surface of the air gap forming layers AGC and the surrounding recesses 28 exposing the upper and lower portions of the flat plate-shaped sheets 13P. Each of the horizontal conductive lines 29 may fill the surrounding recesses 28 and be disposed between the air gap forming layers AGC.

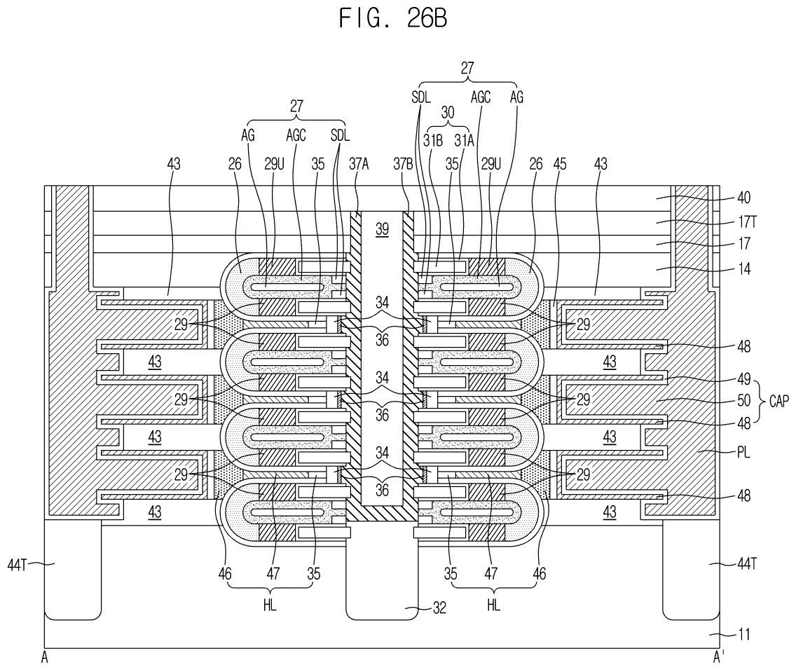

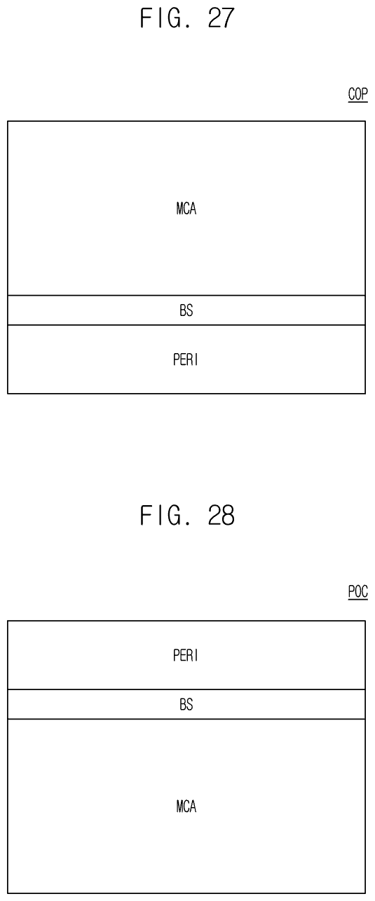

FIGS. 27 and 28 are schematic cross-sectional views of a semiconductor device in accordance with embodiments of the present disclosure.

As illustrated in FIG. 27, a semiconductor device COP may include a memory cell array MCA, a peripheral circuit portion PERI, and a bonding interface BS. The bonding interface BS may be disposed between the memory cell array MCA and the peripheral circuit portion PERI. In the semiconductor device COP, the memory cell array MCA may be disposed at a level higher than the peripheral circuit portion PERI. The semiconductor device COP may be referred to as a “Peri Under Cell array (PUC) structure”. The memory cell array MCA may include a substrate on which back grinding is performed and an array of memory cells. For example, as described with reference to FIG. 26B, after the data storage element CAP is formed, the substrate 11 may be flipped over through a wafer flip, and then the substrate 11 may be partially ground back.

As illustrated in FIG. 28, a semiconductor device POC may include a memory cell array MCA, a peripheral circuit portion PERI, and a bonding interface BS. The bonding interface BS may be disposed between the memory cell array MCA and the peripheral circuit portion PERI. In the semiconductor device POC, the memory cell array MCA may be disposed at a level lower than the peripheral circuit portion PERI. The semiconductor device POC may be referred to as a “Cell array Under Peri (CUP) structure”. Forming the peripheral circuit portion PERI may include forming a plurality of control circuits on a peripheral circuit substrate and forming multi-level interconnection on the control circuits.

In FIG. 27 and FIG. 28, the bonding interface BS may include pad bonding, hybrid bonding, oxide-to-oxide bonding, metal-to-metal bonding, or a combination thereof. The hybrid bonding may refer to a combination of the pad bonding and the oxide-to-oxide bonding. The pad bonding may include forming a cell bonding pad for a memory cell array, forming a peripheral circuit bonding pad for a peripheral circuit portion, performing a wafer flip so that the cell bonding pad and the peripheral circuit bonding pad face each other, and performing wafer bonding.

The semiconductor device COP illustrated in FIG. 27 may perform the wafer flip on the substrate on which the memory cell array is formed so that the cell bonding pad and the peripheral circuit bonding pad face each other, after the cell bonding pad and the peripheral circuit bonding pad are formed. The semiconductor device POC illustrated in FIG. 28 may perform the wafer flip on the substrate on which the peripheral circuit portion is formed so that the cell bonding pad and the peripheral circuit bonding pad face each other, after the cell bonding pad and the peripheral circuit bonding pad are formed.

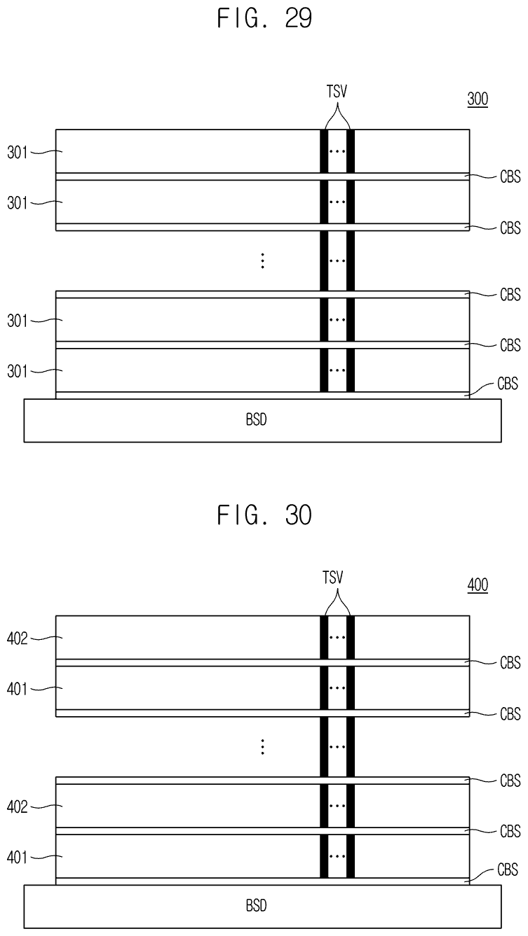

FIGS. 29 and 30 illustrate various views illustrating a stack assembly in accordance with an embodiment of the present disclosure.

As illustrated in FIG. 29, a stack assembly 300 may include an assembly of semiconductor dies. For example, the stack assembly 300 may include a first semiconductor die BSD and a plurality of second semiconductor dies 301. The first semiconductor die BSD may include logic circuits. Each of the second semiconductor dies 301 may include memory cell arrays according to embodiments described above. Each of the second semiconductor dies 301 may include structures in which a memory cell array and a peripheral circuit portion are stacked, for example, the semiconductor device COP illustrated in FIG. 27 or the semiconductor device POC illustrated in FIG. 28. The logic circuits of the first semiconductor die BSD may be different from the peripheral circuit portions of the second semiconductor dies 301. The second semiconductor dies 301 may have chip levels or wafer levels.

The second semiconductor dies 301 may be electrically coupled to each other through a plurality of through silicon vias TSV and bonding interfaces CBS. The first semiconductor die BSD and a lowermost second semiconductor die 301 may be electrically coupled to each other through the bonding interface CBS. The second semiconductor dies 301 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

In some embodiments, the second semiconductor dies 301 may be wafer-flipped and ground back to form the bonding interfaces CBS.

As illustrated in FIG. 30, a stack assembly 400 may include an assembly of semiconductor dies. For example, the stack assembly 400 may include a first semiconductor die BSD, a plurality of second semiconductor dies 401, and a plurality of third semiconductor dies 402. The first semiconductor die BSD may include logic circuits. Each of the second semiconductor dies 401 and each of the third semiconductor dies 402 may include memory cell arrays according to embodiments described above. The second semiconductor dies 401 and the third semiconductor dies 402 may have different structures.

Each of the second semiconductor dies 401 may include the semiconductor device COP illustrated in FIG. 27 in which a memory cell array is stacked over a peripheral circuit portion. Each of the third semiconductor dies 402 may include the semiconductor device POC illustrated in FIG. 28 in which a peripheral circuit portion is stacked over a memory cell array.

In some embodiments, each of the second semiconductor dies 401 may include the semiconductor device POC illustrated in FIG. 28 in which a peripheral circuit portion is stacked over a memory cell array, and each of the third semiconductor dies 402 may include the semiconductor device COP illustrated in FIG. 27 in which a memory cell array is stacked over a peripheral circuit portion.

The logic circuits of the first semiconductor die BSD may be different from the peripheral circuit portions of the second and third semiconductor dies 401 and 402. The second and third semiconductor dies 401 and 402 may have chip levels or wafer levels.

The second and third semiconductor dies 401 and 402 may be electrically coupled to each other through a plurality of through silicon vias TSV and bonding interfaces CBS. The first semiconductor die BSD and a lowermost second semiconductor die 401 may be electrically coupled to each other through the bonding interface CBS. The second and third semiconductor dies 401 and 402 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

In some embodiments, wafer-flip and back grinding may be performed to form the bonding interface CBS. For example, the second semiconductor dies 401 and/or the third semiconductor dies 402 may be wafer-flipped and ground back.

The stack assemblies 300 and 400 illustrated in FIGS. 29 and 30 may be high bandwidth memories.

According to various embodiments of the present disclosure, because air gaps are formed between horizontal conductive lines that are vertically stacked, parasitic capacitance between the horizontal conductive lines that are vertically stacked may be reduced.

While the embodiments of the present disclosure have been illustrated and described with respect to specific embodiments and drawings, the disclosed embodiments are not intended to be restrictive. Further, it is noted that the embodiments of the present disclosure may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A semiconductor device comprising:
a plurality of nano sheets that are vertically stacked;
a first conductive line coupled in common to first edges of the nano sheets, the first conductive line being oriented vertically;
a plurality of data storage elements, each data storage element being coupled to second edges of the nano sheets;
a plurality of second conductive lines, each second conductive line surrounding the nano sheets and being oriented horizontally; and
a plurality of inter-cell dielectric layers disposed between the second conductive lines and each including an air gap.

2. The semiconductor device of claim 1, wherein each of the inter-cell dielectric layers includes an air gap forming layer in which the air gap is embedded.

3. The semiconductor device of claim 2, wherein the air gap forming layer includes silicon oxide.

4. The semiconductor device of claim 1, wherein each of the inter-cell dielectric layers further includes silicon carbon oxide in contact with the first conductive line.

5. The semiconductor device of claim 1, further comprising:
a first spacer disposed between each of the inter-cell dielectric layers and each of the data storage elements; and
a second spacer disposed between each of the inter-cell dielectric layers and the first conductive line.

6. The semiconductor device of claim 1, wherein the first spacer has a shape surrounding the nano sheets at the same horizontal level and covering a side surface of each of the inter-cell dielectric layers.

7. The semiconductor device of claim 1, wherein each of the nano sheets includes a flat plate-shaped sheet in contact with the first conductive line and a fan-shaped sheet in contact with each of the data storage elements.

8. The semiconductor device of claim 7, wherein each of the nano sheets includes first and second doped regions spaced apart from each other in a second direction and a channel between the first doped region and the second doped region, and wherein the first doped region and the channel are disposed in the flat plate-shaped sheet, and the second doped region is disposed in the fan-shaped sheet.

9. The semiconductor device of claim 1, further comprising:
first contact nodes disposed between the nano sheets and the first conductive line; and
second contact nodes disposed between the nano sheets and the data storage elements.

10. The semiconductor device of claim 9, wherein the second contact nodes each include a selective epitaxial growth layer.

11. A method for fabricating a semiconductor device, the method comprising:
forming nano sheet target layers that are vertically stacked and spaced apart from each other over a substrate;
trimming first portions of the nano sheet target layers and forming flat plate-shaped sheets;
forming a first spacer layer defining inner spaces in upper and lower portions of the flat plate-shaped sheets;
forming air gap target layers that fill the inner spaces;
forming strip barrier layers and strip paths between the strip barrier layers at entrances of the inner spaces;
removing the air gap target layers through the strip paths and forming initial air gaps;
forming air gap forming layers filling the initial air gaps and in which air gaps are embedded;
horizontally recessing the first spacer layer to form a first spacer covering side surfaces of the air gap forming layers and surrounding recesses exposing the upper and lower portions of the flat plate-shaped sheets; and
forming horizontal conductive lines filling the surrounding recesses and being disposed between the air gap forming layers.

12. The method of claim 11, wherein the air gap forming layers each include a dielectric material.

13. The method of claim 11, wherein the air gap forming layers each include silicon oxide.

14. The method of claim 11, wherein the air gap target layers each include polysilicon or silicon oxide.

15. The method of claim 11, wherein the strip barrier layers are selectively deposited from an exposed surface of the first spacer layer.

16. The method of claim 11, wherein the strip barrier layers each include silicon carbon oxide, and the first spacer layer includes silicon nitride.

17. The method of claim 11, wherein the nano sheet target layers each include monocrystalline silicon.

18. The method of claim 11, further comprising:
forming first contact nodes coupled to the flat plate-shaped sheets;
forming a vertical conductive line coupled in common to the first contact nodes;
horizontally recessing second portions of the nano sheet target layers and forming fan-shaped sheets;
selectively growing the second contact nodes on side surfaces of the fan-shaped sheets; and
forming data storage elements coupled to the second contact nodes.

19. The method of claim 18, wherein selectively growing the second contact nodes on the side surfaces of the fan-shaped sheets includes growing a doped silicon layer through a selective epitaxial growth.

20. The method of claim 11, wherein the horizontal conductive lines extend while surrounding the flat plate-shaped sheets disposed at the same horizontal level, and each of the air gap forming layers is disposed between the horizontal conductive lines that are vertically stacked.
